(19) United States
(12) Patent Application Publication
(10) Pub. No.: US 2016/0035603 A1
(43) Pub. Date: Feb. 4, 2016

(54) LASER ANNEALING APPARATUS

(71) Applicants: KYUSHU UNIVERSITY, NATIONAL UNIVERSITY CORPORATION, Fukuoka (JP); GIGAPHOTON INC., Tochigi (JP)

(72) Inventors: Hiroshi IKENOUE, Fukuoka (JP); Osamu WAKABAYASHI, Tochigi (JP)

(73) Assignees: GIGAPHOTON INC., Tochigi (JP); KYUSHU UNIVERSITY, NATIONAL UNIVERSITY CORPORATION, Fukuoka (JP)

(21) Appl. No.: 14/854,395

(22) Filed: Sep. 15, 2015

Related U.S. Application Data
(63) Continuation of application No. PCT/JP2014/057291, filed on Mar. 18, 2014.

(30) Foreign Application Priority Data
Mar. 27, 2013 (JP) 2013-066803

(51) Int. Cl. H01L 21/67; B23K 26/00; B23K 26/067

(52) U.S. Cl. CPC H01L 21/67115; B23K 26/067; B23K 26/0081

(57) ABSTRACT

Provided is a laser annealing apparatus that may include: a laser light source section configured to output pulsed laser light to be applied to a thin film formed on a workpiece; a pulse width varying section configured to vary a pulse width of the pulsed laser light; a melt state measuring section configured to detect that the thin film irradiated with the pulsed laser light is in a melt state; and a controlling section configured to determine, based on a result of detection by the melt state measuring section, a duration of time during which the thin film is in the melt state, and to control the pulse width varying section to allow the duration of time to be of a predetermined length.

### CROSS REFERENCE TO RELATED APPLICATIONS

This is a continuation of International Application No. PCT/JP2014/057291, filed Mar. 18, 2014, which claims the benefit of Japanese Priority Patent Application JP2013-066803, filed Mar. 27, 2013, the entire contents of both of which are incorporated herein by reference.

### BACKGROUND

The disclosure relates to a laser annealing apparatus.

In recent years, laser annealing has been as one of techniques of crystallizing an amorphous film formed on a glass substrate or a silicon substrate to form a polycrystalline film. Laser annealing may involve, for example, pulsively applying laser light to an amorphous silicon film formed on a silicon substrate to form a polycrystalline silicon film, with use of a laser annealing apparatus equipped with an excimer laser, etc. Forming a polycrystalline silicon film in this way may allow for formation of thin film transistors. A substrate with thin film transistors formed in this way may be used for liquid crystal display devices, etc. For example, reference is made to Japanese Unexamined Patent Application Publication No. 2007-109943, and specifications of U.S. Pat. Nos. 6,535,531, 6,928,093, and 8,265,109.

### SUMMARY

A laser annealing apparatus according to an embodiment of the disclosure may include: a laser light source section configured to output pulsed laser light to be applied to a thin film formed on a workpiece; a pulse width varying section configured to vary a pulse width of the pulsed laser light; a melt state measuring section configured to detect that the thin film irradiated with the pulsed laser light is in a melt state; and a controlling section configured to determine, based on a result of detection by the melt state measuring section, a duration of time during which the thin film is in the melt state, and to control the pulse width varying section to allow the duration of time to be of a predetermined length.

Another laser annealing apparatus according to an embodiment of the disclosure may include: a laser light source section including pairs of electrodes, and configured to output pulsed laser light to be applied to a thin film formed on a workpiece; a delay circuit configured to provide a time delay from discharge of a first pair of the pairs of electrodes to discharge of a second pair of the pairs of electrodes; a melt state measuring section configured to detect that the thin film irradiated with the pulsed laser light is in a melt state; and a controlling section configured to determine, based on a result of detection by the melt state measuring section, a duration of time during which the thin film is in the melt state, and to control the delay circuit to allow the duration of time to be of a predetermined length.

### BRIEF DESCRIPTION OF THE DRAWINGS

Some example embodiments of the disclosure are described below as mere examples with reference to the accompanying drawings.

FIG. 1 illustrates a configuration of a laser annealing apparatus according to an example embodiment of the disclosure.

FIG. 2 illustrates a configuration of a laser light source section in the laser annealing apparatus according to the example embodiment of the disclosure.

FIG. 3 illustrates a configuration of an optical pulse stretcher.

FIG. 4 is a top view of a portion including a beam splitter in the optical pulse stretcher.

FIG. 5 is a waveform chart of a pulse waveform by the optical pulse stretcher.

FIG. 6 is a correlation diagram between reflectance of the beam splitter and a pulse width TIS.

FIG. 7 is a relation diagram between states of a thin film formed on a workpiece and reflectance.

FIG. 8 is a flowchart (1) illustrating a laser annealing method according to an example embodiment of the disclosure.

FIG. 9 is a flowchart (2) illustrating a laser annealing method according to an example embodiment of the disclosure.

FIG. 10 illustrates a configuration of a laser annealing apparatus including a liquid supplying section according to an example embodiment of the disclosure.

FIG. 11 illustrates a configuration of a laser annealing apparatus including a plurality of optical pulse stretchers.

FIG. 12 is a waveform chart of pulse waveforms by the plurality of optical pulse stretchers.

FIG. 13 illustrates a configuration of a laser light source section including plural pairs of electrodes.

FIG. 14 is a diagram illustrating pulse waveforms outputted from the laser light source section including the plural pairs of electrodes.

FIG. 15 illustrates a configuration (1) of a laser annealing apparatus according to another example embodiment of the disclosure.

FIG. 16 illustrates a configuration (2) of a laser annealing apparatus according to another example embodiment of the disclosure.

FIG. 17 is a relation diagram between states of a thin film formed on a workpiece and transmittance.

FIG. 18 is a flowchart illustrating a laser annealing method according to an example embodiment of the disclosure.

FIGS. 19A and 19B are diagrams illustrating a configuration of another liquid supplying section.

FIG. 20 is a diagram illustrating a PPM and a charger.

FIG. 21 is a diagram illustrating a controlling section.

### DETAILED DESCRIPTION

In the following, some example embodiments of the disclosure are described in detail with reference to the drawings. Example embodiments described below each illustrate one example of the disclosure and are not intended to limit the contents of the disclosure. Also, all of the configurations and operations described in each example embodiment are not necessarily essential for the configurations and operations of the disclosure. Note that the like elements are denoted with the same reference numerals, and any redundant description thereof is omitted.

### [Contents]

[1. Laser Annealing Apparatus including Pulse Width Variable Laser Light Source Section]

### 1.1 Configuration

### 1.2 Operation

### 1.3 Workings

### 1.4 Laser Light Source Section

### 1.4.1 Configuration

### 1.4.2 Operation

### 1.5 Optical Pulse Stretcher

### 1.5.1 Configuration

### 1.5.2 Operation

### 1.6 Measurement of Reflectance in Melt Measuring Section

### 1.7 Laser Annealing Method

### 1.8 Et Cetera

[2. Laser Annealing Apparatus including Liquid Supplying Section]

### 2.1 Configuration

### 2.2 Operation

### 2.3 Workings

### [3. Other Methods of Varying Pulse Width]

### 3.1 Plural Optical Pulse Stretchers

3.2 Excimer Laser Light Source including Plural Pairs of Electrodes

### 3.1.1 Configuration

### 3.1.2 Operation

### 3.1.3 Workings

### [4. Other Examples of Melt Measuring Section]

### 4.1 Measurement of Reflectance

### 4.1.1 Configuration

### 4.1.2 Operation

### 4.1.3 Workings

### 4.2 Measurement of Transmittance

### 4.2.1 Configuration

### 4.2.2 Operation

### 4.2.3 Workings

### 4.2.4 Change in Transmittance in Melt Measuring Section

4.2.5 Measurement of Melt Time Tm and Detection of Aggregation using

### Change in Transmittance

### [5. Other Liquid Supplying Sections]

### [6. Et Cetera]

### 6.1 Power Circuit of Excimer Laser Light Source

### 6.2 Controlling Section

[1. Laser Annealing Apparatus including Pulse Width Variable Laser Light Source Section]

In an existing laser annealing apparatus, it is difficult to control a time duration of a melt state (hereinafter referred to as “melt time”) or melted depth, while suppressing aggregation of a material or ablation, etc. Also, in a case of laser annealing under an atmosphere of pure water, it is difficult to control the melt time or the melted depth, while suppressing the aggregation of the material or evaporation of water, etc.

### [1.1 Configuration]

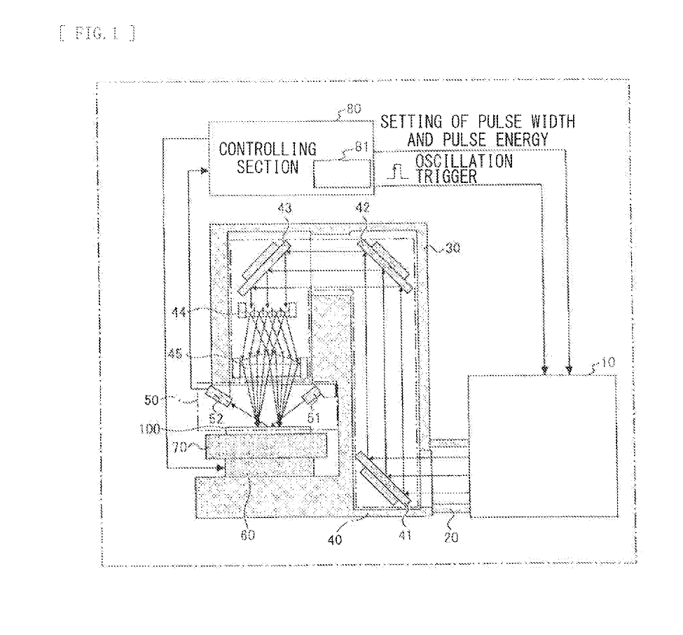

Referring to FIG. 1, a laser annealing apparatus according to one example embodiment of the disclosure may include a laser light source section 10, an optical path tube 20, a frame 30, an optical system 40, a melt state measuring section (hereinafter referred to as a “melt measuring section”) 50, an XYZ stage 60, a table 70, a controlling section 80, etc. The laser light source section 10 may be a laser light source that makes it possible to vary a pulse width, and may include an excimer laser light source configured to output ultraviolet pulsed laser light.

The optical path tube 20 may connect the laser light source section 10 and the frame 30.

The optical system 40 may include a first high reflective mirror 41, a second high reflective mirror 42, a third high reflective mirror 43, a fly eye lens 44, and a condenser optical system 45. The first high reflective mirror 41, the second high reflective mirror 42, the third high reflective mirror 43, the fly eye lens 44, and the condenser optical system 45 may be disposed inside the frame 30. The first high reflective mirror 41, the second high reflective mirror 42, the third high reflective mirror 43, the fly eye lens 44, and the condenser optical system 45 may be so disposed as to allow fluence (energy density per pulse) of pulsed laser light outputted from the laser light source section 10 to be approximately uniform in a predetermined region of a workpiece 100.

The fly eye lens 44, the condenser optical system 45, and the workpiece 100 may be so disposed as to constitute Koehler illumination. For example, the condenser optical system 45 may be so disposed that a front focal position of the condenser optical system 45 is a focal position of the fly eye lens 44, and the workpiece 100 may be disposed at a rear focal position of the condenser optical system 45.

The workpiece 100 may be placed on the table 70. The workpiece 100 may be a substrate made of glass, etc. on a surface of which a thin film such as, but not limited to, amorphous silicon is formed. The table 70 may be fixed to the XYZ stage 60.

The melt measuring section 50 may include a measurement laser light source 51 and a photosensor 52. In one embodiment of the disclosure, the phorosensor 52 may serve as a “light receiving section”. The measurement laser light source 51 and the photosensor 52 may be so disposed that measurement laser light outputted from the measurement laser light source 51 is reflected by a surface of the workpiece 100 and the reflected light is received by the photosensor 52. The measurement laser light source 51 may be a semiconductor laser configured to output laser light with a wavelength ranging from 1 μm to 660 nm both inclusive. Specifically, the measurement laser light source 51 may be a semiconductor laser configured to output laser light with a wavelength of 660 nm.

The controlling section 80 may include a pulse generator 81 configured to generate an oscillation trigger of the pulsed laser light outputted from the laser light source section 10.

### [1.2 Operation]

When the workpiece 100 is placed on the table 70, the controlling section 80 may control the XYZ stage 60 to allow a processing position of the workpiece 100 to be the focal position of the condenser optical system 45.

The controlling section 80 may send a target pulse width and a target pulse energy to the laser light source section 10.

The controlling section 80 may send an oscillation trigger signal to the laser light source section 10. Thereby, the pulsed laser light of the target pulse width and the target pulse energy may be outputted from the laser light source section 10.

The pulsed laser light outputted from the laser light source section 10 may enter the frame 30 through the optical path tube 20. The pulsed laser light entering the frame 30 may be reflected by the first high reflective mirror 41, the second high reflective mirror 42, and the third high reflective mirror 43, and the reflected light may enter the fly eye lens 44.

By the fly eye lens 44, a plurality of secondary light sources may be generated. By the condenser optical system 45, the pulsed laser light may be applied, with approximately uniform fluence, to the predetermined region in the surface of the workpiece 100 disposed in the rear focal plane of the condenser optical system 45.

The application of the pulsed laser light to the workpiece 100 may cause heating of the thin film formed on the workpiece 100, for example, the amorphous silicon film formed on the glass substrate. Thus, laser annealing may be carried out.

In the meanwhile, the laser light outputted from the measurement laser light source 51 of the melt measuring section 50 may be reflected by the thin film, for example, the amorphous silicon film, formed on the workpiece 100, and the reflected light may enter the photosensor 52. The photosensor 52 may continuously detect light intensity of the entering light. A signal of the light intensity detected in the photosensor 52 may be sent to the controlling section 80. Thus, the controlling section 80 may measure temporal change in reflectance of the thin film that is formed on the workpiece 100 and is being subjected to the laser annealing.

Based on the temporal change in reflectance measured in the controlling section 80, determination may be made on the melt time, a post-annealing state, etc. of the thin film formed on the workpiece 100. Determination on the post-annealing state may involve whether the thin film is in a crystallized state or aggregated.

The controlling section 80 may control, based on the melt time and the post-annealing state of the thin film formed on the workpiece 100, to obtain the target pulse width and the target pulse energy in the laser light source section 10, allowing the melt time to come closer to a target melt time Tm.

### [1.3 Workings]

In the melt measuring section 50, the post-annealing state of the thin film formed on the workpiece 100 may be detected. Based on the post-annealing state and the melt time thus detected, the controlling section 80 may control the pulse width and the pulse energy of the pulsed laser light so as to attain the target melt time.

Lengthening the pulse width of the pulsed laser light may make it possible to restrain aggregation in the thin film formed on the workpiece 100 and to crystallize the thin film. It is to be noted that the pulsed laser light with a lengthened pulse width may crystallize a thin film with a larger thickness, as compared to the pulsed laser light with a smaller pulse width.

### [1.4 Laser Light Source Section]

### [1.4.1 Configuration]

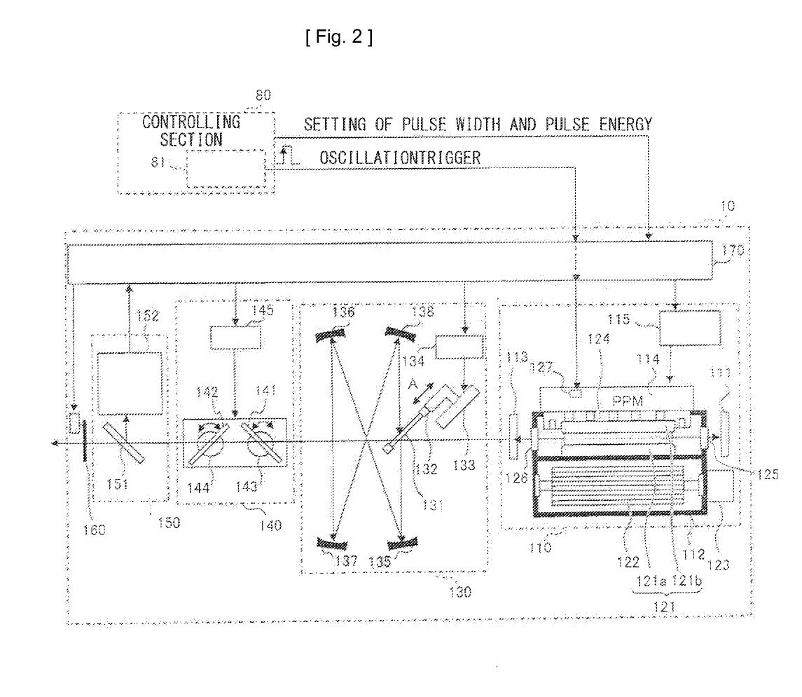

Description is given next of the laser light source section 10 with reference to FIG. 2.

The laser light source section 10 may include an excimer laser light source 110, an optical pulse stretcher (OPS) 130, an attenuator 140, a monitor module 150, a shutter 160, a laser controller 170, etc. In one embodiment of the disclosure, the optical pulse stretcher 130 may serve as a “pulse width varying section”.

On an optical path of the pulsed laser light outputted from the excimer laser light source 110, the optical pulse stretcher 130, the attenuator 140, and the monitor module 150 may be disposed.

The excimer laser light source 110 may include a rear mirror 111, a laser chamber 112, an output coupling mirror 113, a pulse power module (PPM) 114, a charger 115, etc. On an optical path of an optical resonator formed by the rear mirror 111 and the output coupling mirror 113, the laser chamber 112 may be disposed.

The laser chamber 112 may include a pair of electrodes 121, a fan 122, a motor 123, an electrical insulating member 124, two windows 125 and 126, and a laser gas sealed in the laser chamber 112. The pair of electrodes 121 may include one electrode 121a and another electrode 121b. The laser gas may be a mixed gas including a rare gas such as, but not limited to, argon (Ar), krypton (Kr), and xenon (Xe), a halogen gas such as, but not limited to, F₂ gas and Cl₂, and a buffer gas such as, but not limited to, helium (He) and neon (Ne).

The PPM 114 may include a switch 127, a step-up transformer and a magnetic compression circuit which are not illustrated. The charger 115 may be coupled to the PPM 114. An HV signal outputted from the laser controller 170 may be inputted to the charger 115. The oscillation trigger signal outputted from the controlling section 80 may be inputted to the switch 127 through the laser controller 170.

The optical pulse stretcher 130 may include a reflectance distribution beam splitter 131, a holder 132, a uniaxial stage 133, a first driver 134, a first concave mirror 135, a second concave mirror 136, a third concave mirror 137, a fourth concave mirror 138, etc.

The reflectance distribution beam splitter 131 may be so formed as to allow reflectance to change in a direction denoted by an arrow A. The reflectance distribution beam splitter 131 may be configured to move in the direction denoted by the arrow A by the uniaxial stage 133 through the holder 132 while maintaining an entering angle of the pulsed laser light.

The laser controller 170 may be coupled to the uniaxial stage 133 through the first driver 134.

The attenuator 140 may include a first mirror 141, a second mirror 142, a first rotation stage 143, a second rotation stage 144, a second driver 145, etc.

The first mirror 141 and the second mirror 142 each may include a film whose transmittance of the pulsed laser light may change in response to an entering angle of the pulsed laser light.

The first mirror 141 and the second mirror 142 may be disposed on the first rotation stage 143 and the second rotation stage 144 so that an entering angle of the first mirror 141 and an exiting angle of the second mirror 142 of the pulsed laser light coincide with each other. A signal outputted from the laser controller 170 may be inputted to the second driver 145 to control rotation of the first rotation stage 143 and rotation of the second rotation stage 144 in the attenuator 140. Here, the rotation of the first rotation stage 143 and the rotation of the second rotation stage 144 each may be controlled so as to obtain the entering angle at which desired transmittance is obtained, while allowing the entering angle of the first mirror 141 and the exiting angle of the second mirror 142 to coincide with each other.

The monitor module 150 may include a beam splitter 151 and a pulse energy sensor 152. The beam splitter 151 may be disposed on the optical path of the pulsed laser light, and may be configured to reflect part of entering light and to transmit the rest of the entering light. The beam splitter 151 may be so disposed that the light reflected by the beam splitter 151 enters the pulse energy sensor 152. When the light enters the pulse energy sensor 152, in the pulse energy sensor 152, a signal according to pulse energy of the entering pulsed laser light may be outputted. The signal thus outputted may be inputted to the laser controller 170.

The shutter 160 may be disposed on the optical path of the pulsed laser light, and may be a shutter configured to open and close based on a signal from the laser controller 170. The opening of the shutter 160 may allow the light passing through the beam splitter 151 to be outputted from the laser light source section 10.

### [1.4.2 Operation]

The target pulse width TISt and the target pulse energy Et may be inputted to the laser controller 170 from the controlling section 80. In the laser controller 170, in order to obtain the target pulse width TISt, reflectance of the light reflected by the reflectance distribution beam splitter 131 in the optical pulse stretcher 130 may be calculated. The laser controller 170 may control the uniaxial stage 133 through the first driver 134 to locate the reflectance distribution beam splitter 131 at a position where the reflectance distribution beam splitter 131 involves the reflectance thus calculated in the optical path of the laser light.

The laser controller 170 may send, to the charger 115 of the excimer laser light source 110, a signal to obtain a predetermined charged voltage. In the attenuator 140, a signal may be sent to the second driver 145 so as to obtain desired transmittance, allowing the second driver 145 to rotate the first rotation stage 143 and the second rotation stage 144.

The laser controller 170 may send a signal to open and close the shutter 160.

The laser controller 170 may send the oscillation trigger signal to the switch 127 of the PPM 114 in the excimer laser light source 110.

Thus, a pulsed high voltage may be applied between the pair of electrodes 121 in the laser chamber 112, allowing the rare gas and the halogen gas in the laser gas to be excited to become an excimer state.

Light may be released upon returning to a ground state (the rare gas and the halogen gas) from the excimer state. The light thus released may laser oscillate between the rear mirror 111 and the output coupling mirror 113, allowing the pulsed laser light to be outputted through the output coupling mirror 113.

The pulsed laser light outputted from the excimer laser light source 110 may partly pass through, and may be partly reflected by the reflectance distribution beam splitter 131. At this occasion, the pulsed laser light passing through the reflectance distribution beam splitter 131 may enter the attenuator 140. On the other hand, the pulsed laser light reflected by the reflectance distribution beam splitter 131 may be reflected by the first concave mirror 135, the second concave mirror 136, the third concave mirror 137, and the fourth concave mirror 138, and the reflected light may enter the reflectance distribution beam splitter 131 again. Further, the pulsed laser light entering the reflectance distribution beam splitter 131 again may partly pass through, and may be partly reflected by the reflectance distribution beam splitter 131.

At this occasion, the pulsed laser light reflected by the reflectance distribution beam splitter 131 may enter the attenuator 140. On the other hand, the pulsed laser light passing through the reflectance distribution beam splitter 131 may be reflected by the first concave mirror 135, the second concave mirror 136, the third concave mirror 137, and the fourth concave mirror 138, and the reflected light may enter the reflectance distribution beam splitter 131 again.

Here, an optical path of the pulsed laser light reflected by the reflectance distribution beam splitter 131 may be the same as an optical path of the pulsed laser light passing through the reflectance distribution beam splitter 131 for a first time. The pulsed laser light reflected by the reflectance distribution beam splitter 131 may be delayed by an optical path length difference generated by being reflected by the first concave mirror 135, the second concave mirror 136, the third concave mirror 137, and the fourth concave mirror 138.

The optical pulse stretcher 130 may be configured to vary the pulse width of the pulsed laser light in this way. Thereby, the pulsed laser light entering the optical pulse stretcher 130 may be with the target pulse width.

The pulsed laser light exited through the optical pulse stretcher 130 may enter the attenuator 140. The attenuator 140 may transmit the pulsed laser light of desired pulse energy. In the attenuator 140, transmittance may be set so as to allow the pulsed laser light to be with the desired pulse energy.

The pulsed laser light passing through the attenuator 140 may enter the monitor module 150. The pulsed laser light entering the monitor module 150 may be partly transmitted, and may be partly reflected. The light reflected by the beam splitter 151 may enter the pulse energy sensor 152. In the pulse energy sensor 152, the pulse energy of the entering pulsed laser light may be detected. The pulse energy of the pulsed laser light detected by the pulse energy sensor 152 may be sent, as a signal, to the laser controller 170.

The light passing through the beam splitter 151 may be blocked by the shutter 160. The laser controller 170 may perform feedback control, based on the pulse energy of the pulsed laser light detected by the pulse energy sensor 152, so that pulse energy of the pulsed laser light outputted from the excimer laser light source 110 becomes the target pulse energy Et. This feedback control may be one or both of control of the charged voltage in the charger 115 and control of the transmittance in the attenuator 140.

The laser controller 170 may temporarily suspend output of the oscillation trigger signal from the laser controller 170 when a difference (E−Et) between the pulse energy E of the pulsed laser light outputted from the excimer laser light source 110 and the target pulse energy Et is in a predetermined range. Under a production process, the laser annealing may be carried out continuously without suspension of the output of the oscillation trigger signal from the laser controller 170.

The laser controller 170 may send, to the shutter 160, the signal to open the shutter 160. The laser controller 170 may notify the controlling section 80 that the pulse width and the pulse energy reach target values, allowing the oscillation trigger signal from the controlling section 80 to be inputted directly to the switch 127 in the PPM 114.

### [1.5 Optical Pulse Stretcher]

### [1.5.1 Configuration]

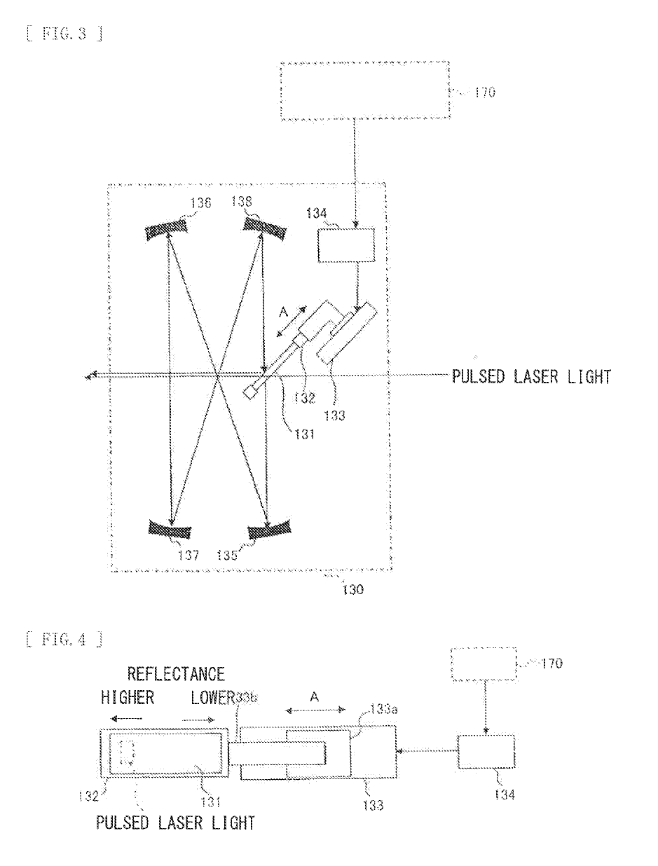

Description is given on a configuration of the optical pulse stretcher 130 with reference to FIGS. 3 and 4.

The optical pulse stretcher 130 may include the reflectance distribution beam splitter 131, the holder 132, the uniaxial stage 133, the first driver 134, the first concave mirror 135, the second concave mirror 136, the third concave mirror 137, and the fourth concave mirror 138, etc.

Radii of curvature of mirror surfaces in the first concave mirror 135, the second concave mirror 136, the third concave mirror 137, and the fourth concave mirror 138 may be the same.

Referring to FIG. 4, the uniaxial stage 133 may include a moving table 133a movable in a direction denoted by an arrow A. A fixing angle 133b may be coupled to the moving table 133a. The holder 132 may be supported by the fixing angle 133b. The reflectance distribution beam splitter 131 may be placed on the holder 132.

The reflectance distribution beam splitter 131 may be placed on the optical path of the pulsed laser light outputted from the excimer laser light source 110.

The first concave mirror 135 and the second concave mirror 136 may be so disposed as to allow the pulsed laser light reflected by the reflectance distribution beam splitter 131 to be reflected by the first concave mirror 135 and to allow the reflected light to enter the second concave mirror 136.

The third concave mirror 137 and the fourth concave mirror 138 may be so disposed as to allow the pulsed laser light reflected by the second concave mirror 136 to be reflected by the third concave mirror 137, to allow the reflected light to be reflected by the fourth concave mirror 138, and to allow the reflected light to enter the reflectance distribution beam splitter 131 again.

It is to be noted that a distance between the reflectance distribution beam splitter 131 and the first concave mirror 135, and a distance between the fourth concave mirror 138 and the reflectance distribution beam splitter 131 each may be approximately a half of the radius of curvature R, i.e., approximately R/2. A distance between the first concave mirror 135 and the second concave mirror 136, a distance between the second concave mirror 136 and the third concave mirror 137, and a distance between the third concave mirror 137 and the fourth concave mirror 138 each may be approximately equal to the radius of curvature R, i.e., approximately R.

Accordingly, the optical path length difference L generated by the first concave mirror 135, the second concave mirror 136, the third concave mirror 137, and the fourth concave mirror 138 may be approximately 4R, i.e., L≈4R.

The reflectance distribution beam splitter 131 may be so formed as to allow the reflectance to change in the direction denoted by the arrow A. The reflectance distribution beam splitter 131 may be configured to move in the direction denoted by the arrow A by the uniaxial stage 133 through the holder 132 while maintaining the entering angle of the pulsed laser light.

An output of the laser controller 170 may be coupled to the uniaxial stage 133 through the first driver 134.

### [1.5.2 Operation]

Description is given next on operation of the optical pulse stretcher 130.

The pulsed laser light outputted from the excimer laser light source 110 may enter the reflectance distribution beam splitter 131. Part of the pulsed laser light may be transmitted and outputted. Part of the pulsed laser light may be reflected. The pulsed laser light thus reflected may be reflected by the first concave mirror 135 and the second concave mirror 136. A beam of the pulsed laser light at the reflectance distribution beam splitter 131 may be focused as a first transfer image. A second transfer image may be focused, by the third concave mirror 137 and the fourth concave mirror 138, at the position of the reflectance distribution beam splitter 131. Part of the pulsed laser light may be reflected with high reflectance and outputted by the reflectance distribution beam splitter 131. The pulsed laser light outputted at this occasion may be outputted at a timing delayed by the optical path length difference L. The pulsed laser light passing through the reflectance distribution beam splitter 131 may be reflected again by the first to the fourth concave mirrors 135 to 138, and the reflected light may enter the reflectance distribution beam splitter 131 again. The light reflected by the reflectance distribution beam splitter 131 may be outputted. The pulsed laser light outputted at this occasion may be outputted at a timing further delayed by the optical path length difference L.

Repetition of the above-described operation may allow for lengthening of the pulse width of the inputted pulsed laser light.

FIG. 5 illustrates a waveform of the pulsed laser light outputted from the excimer laser light source 110 and a waveform of the pulsed laser light pulse-stretched by the optical pulse stretcher 130. It is to be noted that the waveform of the pulsed laser light pulse-stretched by the optical pulse stretcher 130 may be a pulse waveform on conditions that the optical path length difference L equals to 11.5 m (L=11.5 m) and the reflectance in the reflectance distribution beam splitter 131 is 60%.

As illustrated in FIG. 5, by the optical pulse stretcher 130, the pulsed laser light with the pulse width (TIS) of 44 ns outputted from the excimer laser light source 110 may be pulse-stretched to become pulsed laser light with the pulse width (TIS) of 100 ns.

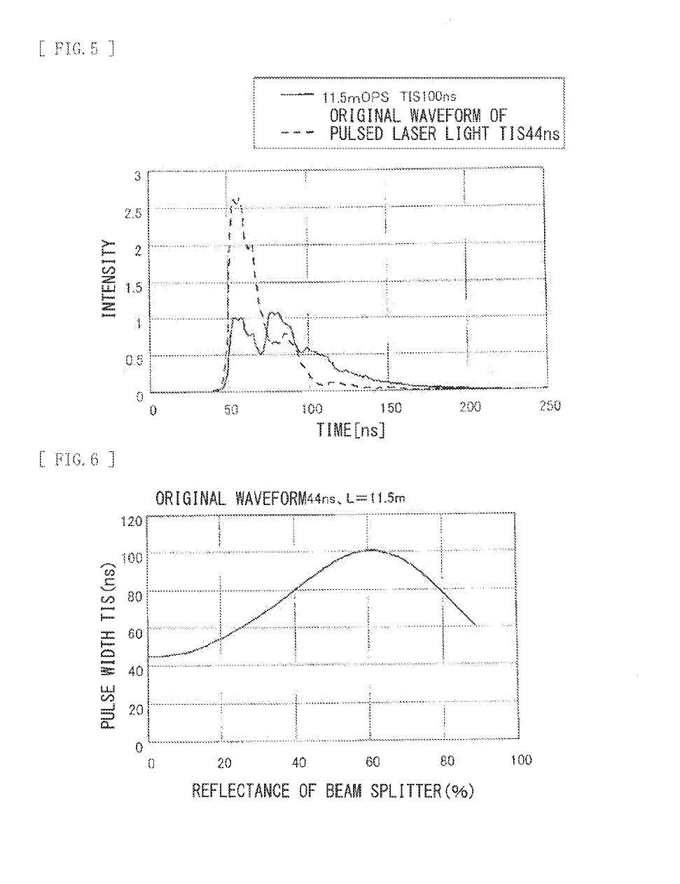

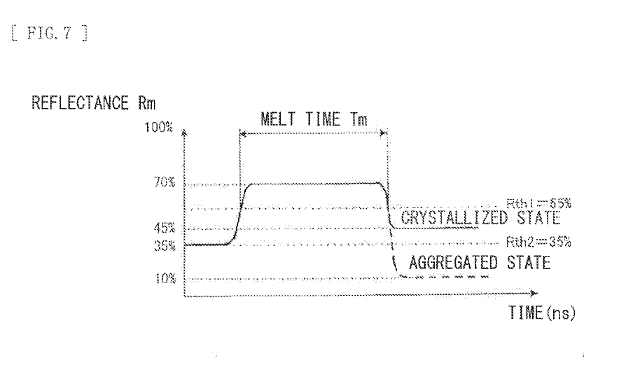

FIG. 6 illustrates relation between the reflectance in the reflectance distribution beam splitter 131 and the pulse width to be pulse-stretched by the optical pulse stretcher 130. Changing the reflectance in the reflectance distribution beam splitter 131 in a range from 0% to 60% both inclusive may allow the pulse width to change in a range from 44 ns to 100 ns both inclusive. The pulse width may therefore be controlled by moving the reflectance distribution beam splitter 131 to change the reflectance of a region which the pulsed laser light enters. The laser controller 170 may store in advance the relation between the reflectance in the reflectance distribution beam splitter 131 and the pulse width TIS as illustrated in FIG. 6, and may calculate the reflectance in the reflectance distribution beam splitter 131 based on the target pulse width TISt. The laser controller 170 may send a control signal to the uniaxial stage 133 so that the reflectance in the reflectance distribution beam splitter 131 becomes the reflectance thus calculated.

In the laser annealing apparatus according to one example embodiment of the disclosure, the pulse width TIS of the pulsed laser light may be defined by an expression denoted by Mathematical Expression 1 in which t denotes time and I(t) denotes light intensity at the time t.

$$TIS = \frac{{[ \int I ( t ) d t ]}^{2}}{\int {I ( t )}^{2} d t} \qquad [ Mathematical Expression 1 ]$$

It is to be noted that the reflectance may be changed by the reflectance distribution beam splitter 131 as a mechanism to allow the optical pulse stretcher 130 to change the pulse width in one example embodiment of the disclosure. However, this example embodiment is not limitative. For example, a plurality of beam splitters with different reflectance from one another may be switched between one another. In another alternative, the pulse width may be controlled by providing a mechanism to change the optical path length difference L and controlling the optical path length difference L, instead of changing reflectance of a beam splitter or beam splitters.

### [1.6 Measurement of Reflectance in Melt Measurement Section]

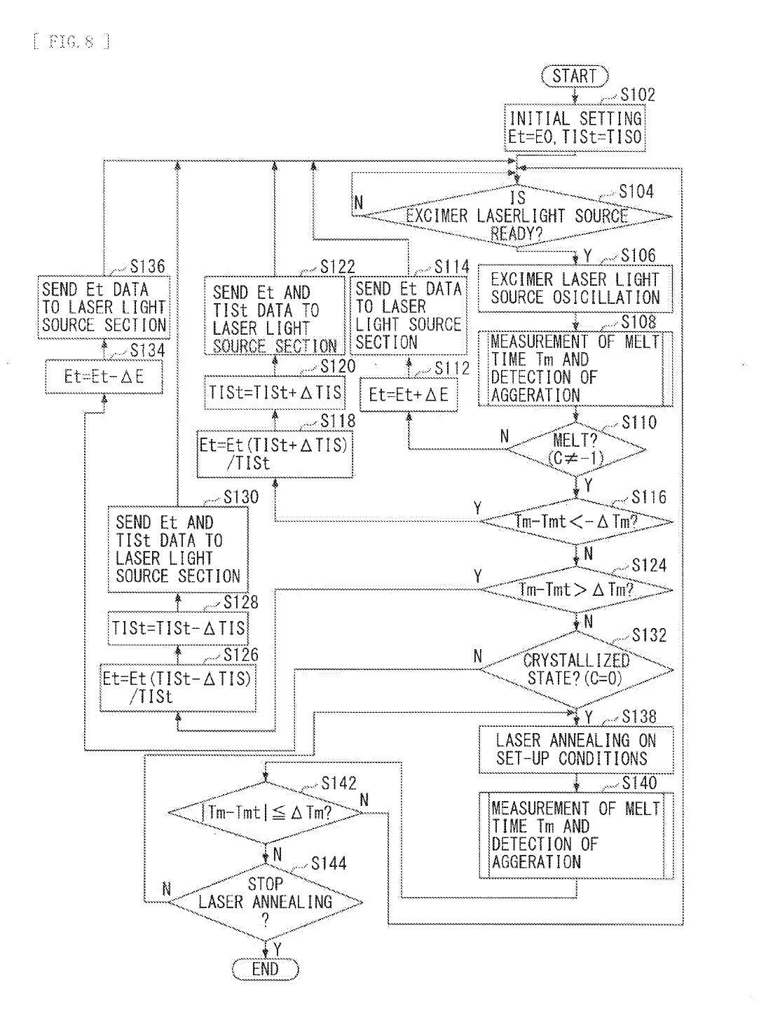

As described above, the laser light outputted from the measurement laser light source 51 in the melt measurement section 50 may be reflected by the thin film formed on the workpiece 100, e.g., the amorphous silicon film, and the reflected light may enter the photosensor 52. The wavelength of the laser light outputted from the measurement laser light source 51 may be 660 nm. As illustrated in FIG. 7, the reflectance of the amorphous silicon film irradiated with the light with the wavelength of 660 nm may be approximately 35%. When the amorphous silicon film is irradiated with the pulsed laser light to melt, i.e., to become a melt state, the reflectance may increase up to approximately 70%. When the irradiation with the pulsed laser light ends, the amorphous silicon film may be cooled and solidified. In such a solidified state, what used to be the amorphous silicon film may become a polysilicon film. The reflectance of the polysilicon film irradiated with the light with the wavelength of 660 nm may be approximately 45%.

It is to be noted that when the amorphous silicon film is irradiated with the pulsed laser light with too high fluence, the silicon constituting the amorphous silicon film may be aggregated, which may cause scattering of the measurement laser light. This may result in a further decrease in the reflectance. At this occasion, the reflectance may be approximately 10%.

Accordingly, as illustrated in FIG. 7, the melt time Tm may be obtained by measuring time during which the measured reflectance is kept higher than a first reflectance reference value Rth1 wherein the first reflectance reference value Rth1=55%, for example. Determination whether the film after the irradiation with the pulsed laser light is in the crystallized state or aggregated may be made by whether or not the reflectance after the irradiation with the pulsed laser light is higher than a second reflectance reference value Rth2 wherein the second reflectance reference value Rth2=35%, for example. Specifically, determination of the crystallized state may be made when the reflectance after the irradiation with the pulsed laser light is higher than the second reflectance reference value Rth2, while determination of aggregation may be made when the reflectance after the irradiation with the pulsed laser light is not higher than the second reflectance reference value Rth2.

### [1.7 Laser Annealing Method]

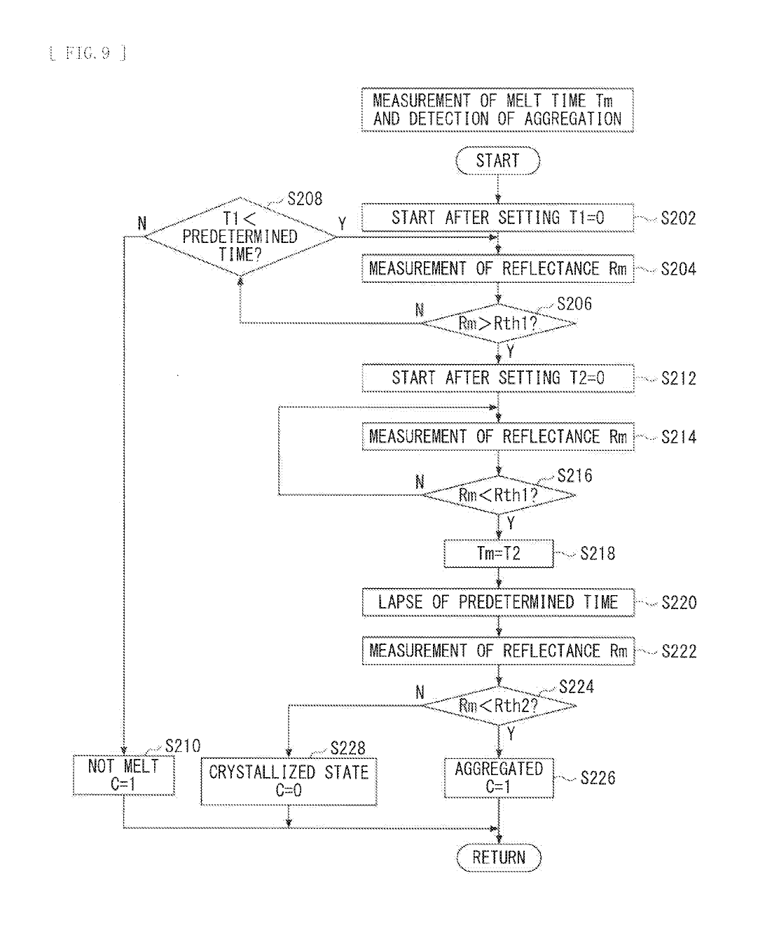

Description is made next on a laser annealing method with the laser annealing apparatus according to one example embodiment of the disclosure with reference to FIG. 8.

First, in step 102 (S102), initial setting may be performed. Specifically, the target pulse energy Et of the pulsed laser light may be set to an initial target pulse energy E0, and the target pulse width TISt may be set to an initial target pulse width TIS0.

Next, in step 104 (S104), determination may be made whether or not the excimer laser light source 110 is ready for laser oscillation. When the excimer laser light source 110 is determined as being ready for laser oscillation, the flow may proceed to step 106. When the excimer laser light source 110 is determined as not being ready for laser oscillation, the step 104 may be repeated.

Next, in the step 106 (S106), the excimer laser light source 110 may be allowed to oscillate. Specifically, the oscillation trigger may be sent to the excimer laser light source 110 from the controlling section 80 through the laser controller 170, allowing the excimer laser light source 110 to oscillate upon receiving the oscillation trigger. From the excimer laser light source 110 thus oscillating, the pulsed laser light with the target pulse energy Et and the target pulse width TISt may be outputted. The pulsed laser light thus outputted may be applied, through the optical pulse stretcher 130, etc., to the thin film formed on the surface of the workpiece 100, e.g., the amorphous silicon film. The amorphous silicon film formed on the surface of the workpiece 100 may melt by the irradiation with the pulsed laser light.

Next, in step 108 (S108), measurement of the melt time Tm and detection of aggregation may be carried out. Specifically, a subroutine of the measurement of the melt time Tm and the detection of aggregation, which is described later, may be carried out. It is to be noted that in the subroutine of the measurement of the melt time Tm and the detection of aggregation, “0” may be raised to a flag C when the thin film formed on the surface of the workpiece 100 is crystallized. When the thin film formed on the surface of the workpiece 100 is aggregated, “1” may be raised to the flag C. When the thin film formed on the surface of the workpiece 100 has not melted, “−1” may be raised to the flag C.

Next, in step 110 (S110), determination may be made whether or not the thin film formed on the surface of the workpiece 100 has melted. Specifically, the determination may be made by whether or not the flag C raised in the subroutine of the measurement of the melt time Tm and the detection of the aggregation, which is described later, is “−1”. When the flag C is “−1”, the thin film may be determined as not having melted, and the flow may proceed to step 112. When the flag C is not “−1”, the thin film may be determined as having melted, and the flow may proceed to step 116.

In the step 112 (S112), in the controlling section 80, etc., a predetermined energy adjustment value ΔE may be added to the current target pulse energy Et to set a new target pulse energy Et.

Next, in step 114 (S114), the target pulse energy Et newly set in the step 112 may be sent to the laser light source section 10. After sending the target pulse energy Et to the laser light source section 10, the flow may proceed to the step 104.

In the step 116 (S116), in the controlling section 80, etc., determination may be made whether or not a value obtained by subtracting a predetermined target melt time Tmt from the melt time Tm measured in the step 108 is smaller than a predetermined melt time difference−ΔTm. That is, determination may be made whether or not Tm−Tmt<−ΔTm is satisfied. When Tm−Tmt<−ΔTm is satisfied, the flow may proceed to step 118. When Tm−Tmt<−ΔTm is not satisfied, the flow may proceed to step 124.

In the step 118 (S118), in the controlling section 80, etc., a new target pulse energy Et may be obtained by multiplying the current target pulse energy Et by a value obtained by dividing a sum of the target pulse width TISt and a predetermined pulse width adjustment value ΔTIS by the target pulse width TISt. In other words, a value obtained by multiplying the current target pulse energy Et by (TISt+ΔTIS)/TISt may be set as the new target pulse energy Et.

Next, in step 120 (S120), a value obtained by adding the predetermined pulse width adjustment value ΔTIS to the current target pulse width TISt may be set as a new target pulse width TISt.

Next, in step 122 (S122), the target pulse energy Et newly set in the step 118 and the target pulse width TISt newly set in the step 120 may be sent to the laser light source section 10. After sending the target pulse energy Et and the target pulse width TISt to the laser light source section 10, the flow may proceed to the step 104.

In the step 124 (S124), determination may be made whether or not a value obtained by subtracting the predetermined target melt time Tmt from the melt time Tm measured in the step 108 is larger than the predetermined melt time difference ΔTm. That is, determination may be made whether or not Tm−Tmt>ΔTm is satisfied. When Tm−Tmt>ΔTm is satisfied, the flow may proceed to step 126. When Tm−Tmt>ΔTm is not satisfied, the flow may proceed to step 132.

In the step 126 (S126), in the controlling section 80, etc., a new target pulse energy Et may be obtained by multiplying the current target pulse energy Et by a value obtained by dividing a difference between the target pulse width TISt and the predetermined pulse width adjustment value ΔTIS by the target pulse width TISt. That is, a value obtained by multiplying the current target pulse energy Et by (TISt−ΔTIS)/TISt may be set as a new target pulse energy Et.

Next, in step 128 (S128), in the controlling section 80, etc., a value obtained by subtracting the predetermined pulse width adjustment value ΔTIS from the current target pulse width TISt may be set as a new target pulse width TISt.

Next, in step 130 (S130), the target pulse energy Et newly set in the step 126 and the target pulse width TISt newly set in the step 128 may be sent to the laser light source section 10. After sending the target pulse energy Et and the target pulse width TISt to the laser light source section 10, the flow may proceed to the step 104.

In the step 132 (S132), determination may be made whether or not the thin film on the surface of the workpiece 100 irradiated with the pulsed laser light is in the crystallized state. Specifically, the determination may be made by whether or not the flag C raised in the subroutine of the measurement of the melt tine Tm and the detection of aggregation, which is described later, is “0”. When the flag C is “0”, the thin film on the surface of the workpiece 100 is determined as being in the crystallized state, i.e., being polycrystalline, and the flow may proceed to step 138. When the flag C is not “0”, the thin film on the surface of the workpiece 100 is determined as not being in the crystallized state, i.e., not being polycrystalline, and the flow may proceed to step 134.

In the step 134 (S134), in the controlling section 80, etc., a new target pulse energy Et may be set by subtracting the predetermined energy adjustment value ΔE from the current target pulse energy Et.

Next, in step 136 (S136), the target pulse energy Et newly set in the step 134 may be sent to the laser light source section 10. After sending the target pulse energy Et to the laser light source section 10, the flow may proceed to the step 104. It is to be noted that the steps 102 to 136 may be setting of laser annealing conditions before actual production.

In the step 138 (S138), the laser annealing of the thin film formed on the workpiece 100 in the production process may be carried out on the conditions set in the foregoing.

Next, in step 140 (S140), the measurement of the melt time Tm and the detection of aggregation may be carried out while performing the laser annealing of the thin film formed on the workpiece 100 in the production process. Specifically, the subroutine of the measurement of the melt time Tm and the detection of aggregation, which is described later, may be carried out.

Next, in step 142 (S142), determination may be made whether or not a difference between the melt time Tm measured in the step 140 and the predetermined melt time Tmt is equal to or smaller than the predetermined melt time difference ΔTm. That is, determination may be made whether or not |Tm−Tmt|≦ΔTm is satisfied. When |Tm−Tmt|≦ΔTm is satisfied, the flow may proceed to step 144. When |Tm−Tmt|≦ΔTm is not satisfied, the flow may proceed to the step 104.

In the step 144 (S144), determination may be made whether or not the laser annealing is to be stopped. When determination to stop the laser annealing is made, the laser annealing may be ended. When determination not to stop the laser annealing is made, the flow may proceed to the step 138.

Description is made next on the subroutine of the measurement of the melt time Tm and the detection of aggregation in the steps 108 and 140 with reference to FIG. 9.

First, in step 202 (S202), time T1 of an undepicted first timer in the controlling section 80, etc. may be set to 0. Thereafter, the first timer may be started.

Next, in step 204 (S204), reflectance Rm of the thin film formed on the workpiece 100 may be measured. Specifically, the reflectance Rm may be measured as follows; the thin film formed on the workpiece 100 may be irradiated with the laser light outputted from the measurement laser light source 51 in the melt measuring section 50, and an amount of light reflected by the thin film may be measured by the photosensor 52.

Next, in step 206 (S206), determination may be made whether or not the reflectance Rm measured in the step 204 is higher than the first reflectance reference value Rth1. When the reflectance Rm measured in the step 204 is determined as being higher than the first reflectance reference value Rth1, the flow may proceed to step 212. When the reflectance Rm measured in the step 204 is determined as not being higher than the first reflectance reference value Rth1, the flow may proceed to step 208.

In the step 208 (S208), determination may be made whether or not the time T1 is shorter than predetermined time. The predetermined time may be, for example, a same value as the pulse width of the pulsed laser light outputted from the excimer laser light source 110. When the time T1 is determined as not being shorter than the predetermined time, the flow may proceed to step 210. When the time T1 is determined as being shorter than the predetermined time, the flow may proceed to the step 204.

In the step 210 (S210), the thin film formed on the workpiece 100 may be determined as not having melted, and “−1” may be raised to the flag C in the controlling section 80, etc.

In the step 212 (S212), time T2 of an undepicted second timer in the controlling section 80, etc. may be set to 0. Thereafter, the second timer may be started.

Next, in step 214 (S214), the reflectance Rm of the thin film formed on the workpiece 100 may be measured. Specifically, the reflectance Rm may be measured in a similar manner to the step 204.

Next, in step 216 (S216), determination may be made whether or not the reflectance Rm measured in the step 214 is lower than the first reflectance reference value Rth1. When the reflectance Rm measured in the step 214 is determined as being lower than the first reflectance reference value Rth1, the flow may proceed to step 218. When the reflectance Rm measured in the step 214 is determined as not being lower than the first reflectance reference value Rth1, the flow may proceed to the step 214.

In the step 218 (S218), a value of the time T2 may be set to Tm.

Next, in step 220 (S220), a lapse of predetermined time may be expected. The predetermined time may be time necessary to determine exactly whether or not the thin film formed on the workpiece 100 is in the crystallized state or aggregated.

Next, in step 222 (S222), the reflectance Rm of the thin film formed on the workpiece 100 may be measured. Specifically, the reflectance Rm may be measured in the similar manner to the step 204.

Next, in step 224 (S224), determination may be made whether or not the reflectance Rm measured in the step 222 is lower than the second reflectance reference value Rth2. When the reflectance Rm measured in the step 222 is determined as being lower than the second reflectance reference value Rth2, the flow may proceed to step 226. When the reflectance Rm measured in the step 222 is determined as not being lower than the second reflectance reference value Rth2, the flow may proceed to step 228.

In the step 226 (S226), the thin film formed on the workpiece 100 may be determined as being aggregated, and “1” may be raised to the flag C in the controlling section 80, etc.

In the step 228 (S228), the thin film formed on the workpiece 100 may be determined as being in the crystallized state, and “0” may be raised to the flag C in the controlling section 80, etc.

Here, when processing should fail in catching up with execution of the above-described flowchart, measurement data of the photosensor 52 may be temporarily written in an undepicted storage section in the controlling section 80, etc. After completion of the measurement of the photosensor 52, data stored in the undepicted storage section in the controlling section 80, etc. may be read out to exert the above-described flowchart.

### [1.8 Et Cetra]

In the forgoing, description is given on the laser annealing apparatus with use of the excimer laser light source 110. However, the laser annealing apparatus according to one example embodiment of the disclosure may use a light source configured to output, for example, harmonic light of YAG laser, instead of the excimer laser light source 110. Specifically, a solid state laser light source configured to output pulsed laser light of a second harmonic wave with a wavelength of 532 nm, a third harmonic wave with a wavelength of 355 nm, and a fourth harmonic wave with a wavelength of 266 nm may be possibly used.

Also, in the forgoing, description is given on a case in which the attenuator 140 and the optical pulse stretcher 130 may be provided inside the laser light source section 10, but this is not limitative. Specifically, any location on an optical path from the excimer laser light source 110 to the fly eye lens 44 may be possible. In this case, the controlling section 80 may control the attenuator 140 and the optical pulse stretcher 130.

Moreover, in the laser annealing apparatus according to one example embodiment of the disclosure, instead of the fly eye lens 44, a diffraction optical device with similar functions may be used. The substrate that constitutes the workpiece 100 is not limited to a glass substrate. Non-limited examples of the substrates that constitute the workpiece 100 may include a resin substrate such as, but not limited to, a PEN (Polyethylene naphthalate) substrate, a PET (Polyethylene terephtahlate) substrate, a PI (polyimide) substrate, and a PC (polycarbonate) substrate.

Furthermore, the thin film formed on the workpiece 100 is not limited to the amorphous silicon film. Amorphous films of, for example, Ge, Si, and SiGe mixtures may be also possible. Amorphous films of these mixtures further including Sn may be possible as well.

In addition, the thin film formed on the workpiece 100 may be a compound semiconductor thin film such as, but not limited to, IGZO, ZnO, GaN, GaAs, and InP. Further, a film transparent with respect to laser light, e.g., a SiO₂ film, may be formed on these films.

[2. Laser Annealing Apparatus including Liquid Supplying Section]

### [2.1 Configuration]

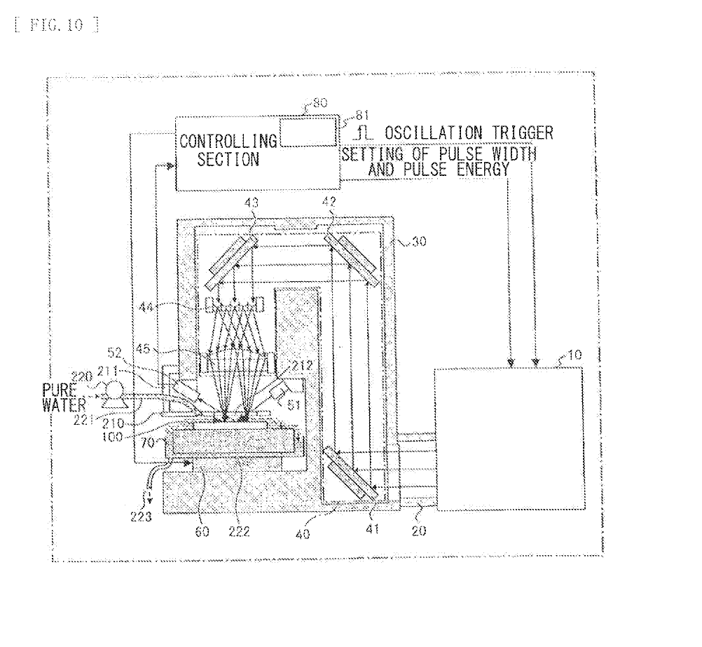

Description is made next on a laser annealing apparatus including a liquid supplying section with reference to FIG. 10. The laser annealing apparatus including the liquid supplying section may include the liquid supplying section in addition to the laser annealing apparatus illustrated in FIG. 1.

A liquid to be supplied by the liquid supplying section may be, for example, pure water. The liquid supplying section may include a plate 210, a plate fixing holder 211, a pump 220 configured to supply the pure water, a pipe 221, a liquid collection vessel 222, and a drain 223.

The plate 210 may be provided with a window 212. The window 212 may be made of a material that makes it possible to transmit the pulsed laser light. A lower surface of the window 212 and a lower surface of the plate 210 may be disposed in a same plane. The window 212 may be attached to the plate 210 so that almost no gap is produced between the window 212 and the plate 210. A constituent material of the window 212 may be synthetic quartz. A constituent material of the plate 210 may be Teflon (registered trademark).

The plate 210 may be fixed to the frame 30 by the plate fixing holder 211. At this occasion, the plate 210 may be placed to allow the pulsed laser light to pass through the window 212 and to be applied to the workpiece 100. Further, the plate 210 may be placed to maintain a predetermined distance between the workpiece 100 and the lower surface of the window 212.

The pump 220 may be placed to allow the pure water to be supplied to the tube 221. The tube 221 may be coupled to the plate 210 at a predetermined angle so that the pure water supplied through the pump 220 flows between the window 212 and the workpiece 100.

The liquid collection vessel 222 may be placed at a position at which the pure water flowing between the window 212 and the workpiece 100 may flow down. The liquid collection vessel 222 may be provided with the drain 223 to discharge the pure water stored in the liquid collection vessel 222.

### [2.2 Operation]

In the liquid supplying section, the pure water may be supplied between the plate 210 and the workpiece 100 by the pump 220 through the tube 221.

The pulsed laser light may pass through the window 212 and the pure water and may be applied to the thin film formed on the workpiece 100. The thin film formed on the workpiece 100 may melt according to the pulse width and the fluence of the pulsed laser light thus applied.

The pure water supplied between the plate 210 and the workpiece 100 may be collected in the liquid collection vessel 222 and may be discharged through the drain 223.

### [2.3 Workings]

The laser annealing may be carried out in an atmosphere of the pure water, making it possible to apply the pulsed laser light with even higher fluence, as compared to a case of laser annealing in an air atmosphere, etc. Hence, it is possible to enhance crystallinity of the thin film on the workpiece 100.

It is also possible to crystallize the thin film on the workpiece 100 even when the thin film formed on the workpiece 100 is with a thickness as large as, for example, 1 μm, etc.

### [3. Other Methods of Varying Pulse Width]

### [3.1 Plural Optical Pulse Stretchers]

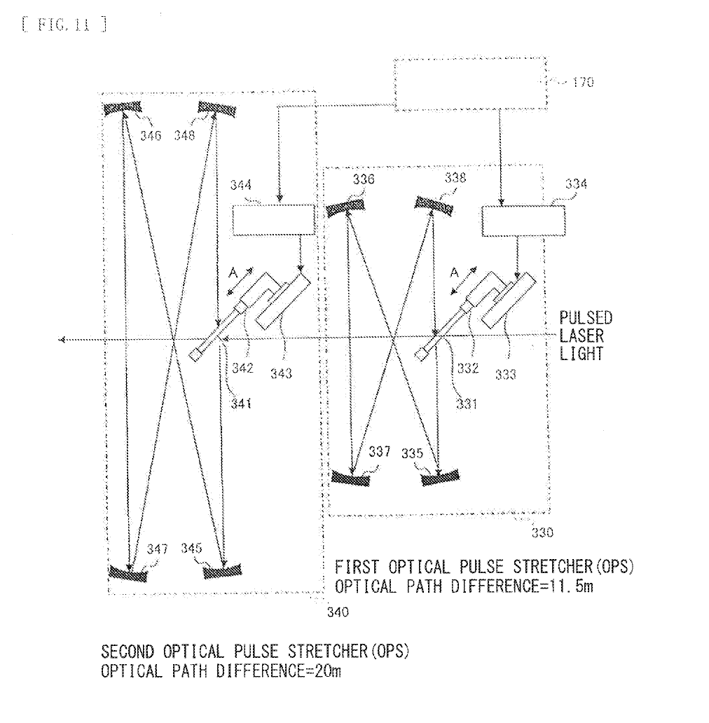

In order to vary the pulse width, a plurality of optical pulse stretchers may be provided as illustrated in FIG. 11. Specifically, a first optical pulse stretcher 330 and a second optical pulse stretcher 340 may be provided. The second optical pulse stretcher 340 may be disposed at a position at which the pulsed laser light outputted from the first optical pulse stretcher 330 may enter the second optical pulse stretcher 340.

The first optical pulse stretcher 330 may include a reflectance distribution beam splitter 331, a holder 332, a uniaxial stage 333, a driver 334, a first concave mirror 335, a second concave mirror 336, a third concave mirror 337, a fourth concave mirror 338, etc.

The second optical pulse stretcher 340 may include a reflectance distribution beam splitter 341, a holder 342, a uniaxial stage 343, a driver 344, a first concave mirror 345, a second concave mirror 346, a third concave mirror 347, a fourth concave mirror 348, etc.

The first optical pulse stretcher 330 and the second optical pulse stretcher 340 each may be an optical pulse stretcher configured to operate similarly to the optical pulse stretcher 130 illustrated in FIG. 3, etc.

The first optical pulse stretcher 330 may be placed to obtain the optical path length difference of 11.5 m. The second optical pulse stretcher 340 may be placed to obtain the optical path length difference of 20 m. The pulsed laser light may enter the reflectance distribution beam splitter 331 at a position at which the reflectance of the reflectance distribution beam splitter 331 is 60%. The pulsed laser light may enter the reflectance distribution beam splitter 341 at a position at which the reflectance of the reflectance distribution beam splitter 341 is 60%.

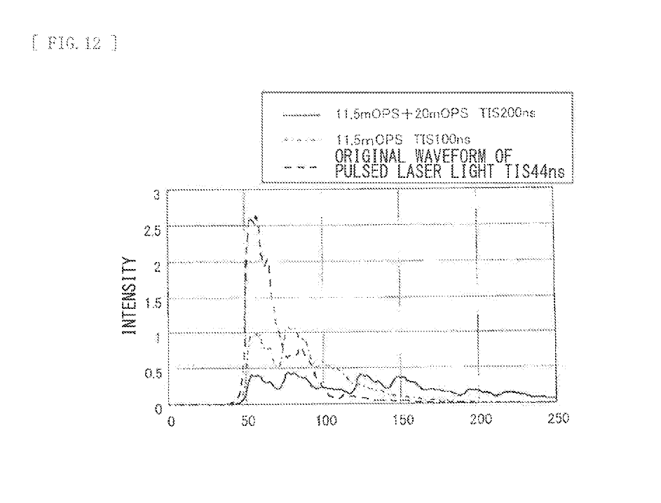

Thereby, as illustrated in FIG. 12, the pulsed laser light with the pulse width (TIS) of 44 ns may be pulse-stretched to the pulsed laser light with the pulse width (TIS) of 200 ns. Thus, in a case illustrated in FIG. 11, the pulse width of the pulsed laser light may be varied in a range from 44 ns to 200 ns both inclusive by controlling the uniaxial stages 333 and 343.

[3.2 Excimer Laser Light Source including Plural Pairs of Electrodes]

### [3.2.1 Configuration]

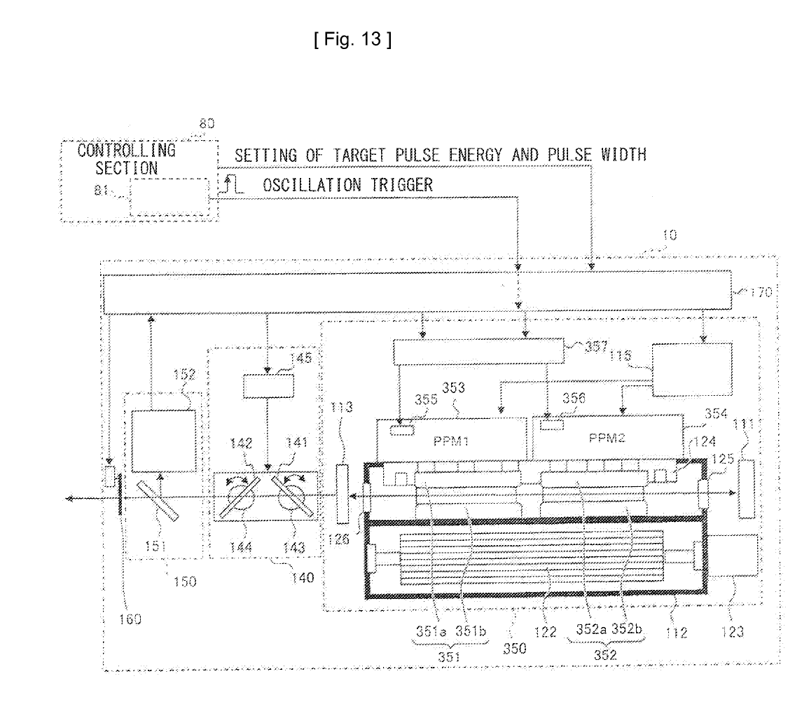

In order to vary the pulse width, the excimer laser light source may be provided with plural pairs of electrodes as illustrated in FIG. 13. In this case, the plural pairs of electrodes may correspond to a “pulse width varying section” in one embodiment of the disclosure.

As illustrated in FIG. 13, a first pair of electrodes 351 and a second pair o f electrodes 352 may be provided in the laser chamber 112 of an excimer laser light source 350. A first PPM 353 may be coupled to the first pair of electrodes 351. A second PPM 354 may be coupled to the second pair of electrodes 352. The first pair of electrodes 351 may include one electrode 351a and another electrode 351b. The second pair of electrodes 352 may include one electrode 352a and another electrode 352b.

The first PPM 353 may include a switch 355, a step-up transformer and a magnetic compression circuit which are not illustrated. The second PPM 354 may include a switch 356, a step-up transformer and a magnetic compression circuit which are not illustrated. The charger 115 may be coupled to the first PPM 353 and the second PPM 354. The HV signal outputted from the laser controller 170 may be inputted to the charger 115. The oscillation trigger signal outputted from the controlling section 80 may be inputted to the switches 355 and 356 through the laser controller 170 and a delay circuit 357.

The optical pulse stretcher may be omitted.

### [3.2.2 Operation]

The laser controller 170 may receive the target pulse width TISt and the target pulse energy Et from the controlling section 80. Upon receiving the target pulse width TISt and the target pulse energy Et, the laser controller 170 may set, in the delay circuit 357, delay time so as to obtain the target pulse width TISt. Also, the laser controller 170 may perform setting of the charged voltage of the charger 115 and the transmittance of the attenuator 140 so as to obtain the target pulse energy Et. The laser controller 170 may store in advance data on measurement of relation between the delay time and the pulse width, and may calculate the delay time based on the data.

The laser controller 170 may send the oscillation trigger signal to the delay circuit 357. The delay circuit 357 may send a signal to the switches 355 and 356 at the delay time thus set. At this occasion, the delay circuit 357 may send the signal to the switch 356 after a lapse of the delay time thus set after sending the signal to the switch 355.

Thus, a pulsed high voltage may be applied to the first pair of electrodes 351, allowing discharge to be generated. Thereafter, a high voltage may be applied to the second pair of electrodes 352 with a predetermined time delay, allowing discharge to be generated.

The discharge in the laser chamber 112 may cause light emission. The light thus emitted may laser oscillate between the output coupling mirror 113 and the rear mirror 111, allowing the pulsed laser light with the long pulse width as illustrated in FIG. 14 to be outputted through the output coupling mirror 113.

The pulsed laser light outputted from the excimer laser light source 350 may enter the attenuator 140. The attenuator 140 may transmit the pulsed laser light with the desired pulse energy. In the attenuator 140, the transmittance may be set to allow the puled laser light to involve the desired pulse energy.

The pulsed laser light passing through the attenuator 140 may enter the monitor module 150. The pulsed laser light entering the monitor module 150 may be partly transmitted and may be partly reflected. The light reflected by the beam splitter 151 may enter the pulse energy sensor 152. In the pulse energy sensor 152, the pulse energy of the entering pulsed laser light may be detected. The pulse energy of the pulsed laser light detected by the pulse energy sensor 152 may be sent, as a signal, to the laser controller 170.

The light passing through the beam splitter 151 may be blocked by the shutter 160. The laser controller 170 may perform feedback control, based on the pulse energy of the pulsed laser light detected by the pulse energy sensor 152, so that the pulse energy of the pulsed laser light outputted from the excimer laser light source 350 becomes the target pulse energy Et. This feedback control may be one or both of the control of the charged voltage in the charger 115 and the control of the transmittance in the attenuator 140.

The laser controller 170 may suspend the output of the oscillation trigger signal from the laser controller 170 when the difference (E−Et) between the pulse energy E of the pulsed laser light outputted from the excimer laser light source 350 and the target pulse energy Et is in a predetermined range. Alternatively, the laser annealing may be carried out continuously without the suspension of the output of the oscillation trigger signal from the laser controller 170.

The laser controller 170 may send, to the shutter 160, the signal to open the shutter 160. The laser controller 170 may notify the controlling section 80 that the pulse width and the pulse energy reach the target values, allowing the oscillation trigger signal from the controlling section 80 to be inputted directly to the delay circuit 357.

### [3.2.3 Workings]

In the laser light source section illustrated in FIG. 13, the pulse width may be lengthened by shifting discharge timings of the two pairs of electrodes, i.e., the first pair of electrodes 351 and the second pair of electrodes 352.

In the forgoing, description is given on a case of shifting the discharge timings with use of the two pairs of electrodes, but the number of pairs of electrodes is not limited to two. Three or more pairs of electrodes may be provided and the discharge timings thereof may be shifted. Thus, the pulse width of the pulsed laser light may be further lengthened.

Moreover, when the laser light source section includes a laser light source configured to output harmonic light of YAG laser including a Q switch, the pulse width may be controlled by means of operation time of the Q switch.

### [4. Other Examples of Melt Measuring Section]

### [4.1 Measurement of Reflectance]

### [4.1.1 Configuration]

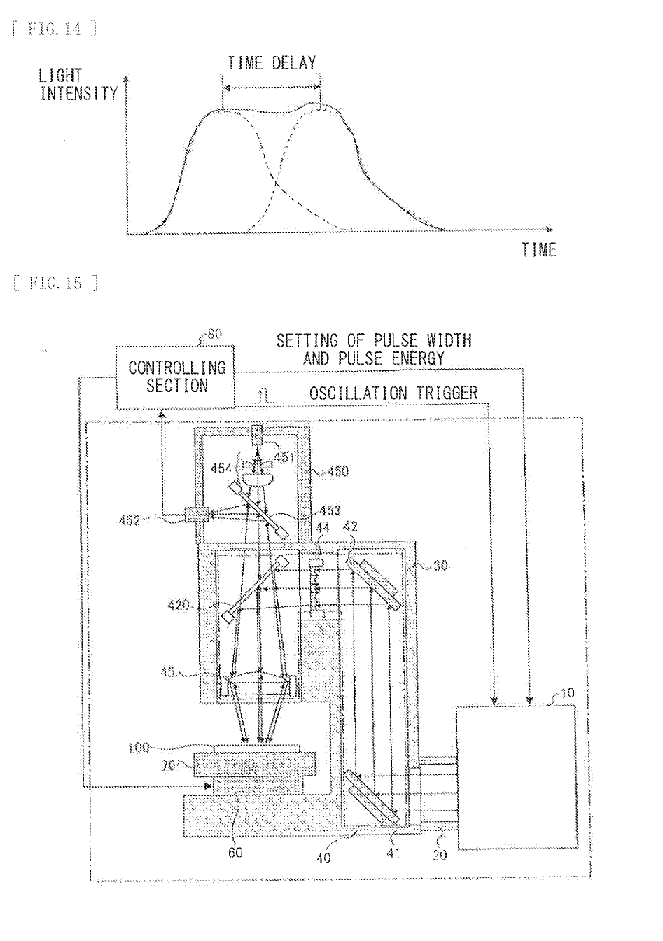

The melt measuring section in the laser annealing section according to one example embodiment of the disclosure may use a melt measuring section configured to measure reflectance and involving a configuration illustrated in FIG. 15.

Specifically, a beam splitter 420 may be provided instead of the third high reflective mirror 43 in the laser annealing apparatus illustrated in FIG. 1, etc.

On the beam splitter 420, a film may be formed that is configured to reflect the excimer laser light with high reflectance and to transmit the measurement laser light with the wavelength of 660 nm with high transmittance.

The fly eye lens 44 may be disposed on an optical path between the second high reflective mirror 42 and the beam splitter 420. The fly eye lens 44 may be formed to involve a smaller beam spread angle, i.e., to involve a spread angle that may allow the entire light to enter the condenser optical system 45, as compared to the fly eye lens 44 illustrated in FIG. 1.

The melt measuring section 450 may include a measurement laser light source 451, a photosensor 452, a beam splitter 453, and a beam spread adjusting optical system 454. In one embodiment of the disclosure, the phorosensor 452 may serve as a “light receiving section”.

The melt measuring section 450 may be placed at a position to allow the measurement laser light outputted from the melt measuring section 450 to be applied to the thin film on the workpiece 100 through the beam splitter 420 and the condenser optical system 45. In other words, the melt measuring section 450 may be placed to allow the beam splitter 420 to be located between the melt measuring section 450 and the condenser optical system 45.

On the optical path of the measurement laser light outputted from the measurement laser light source 451, the beam spread adjusting optical system 454 and the beam splitter 453 may be disposed. The beam spread adjusting optical system 454 may include a concave lens and a convex lens, and may adjust beam spread by controlling a distance between the concave lens and the convex lens.

The measurement laser light source 451 may be placed to allow an optical path of the measurement laser light passing through the beam splitter 420 to be approximately the same as the optical path of the pulsed laser light for annealing.

The beam spread adjusting optical system 454 may be adjusted to allow the measurement laser light to be applied to an approximately same region as the region of the workpiece 100 irradiated with the pulsed laser light.

The measurement laser light outputted from the measurement laser light source 451 may pass through the beam splitters 453 and 420 through the beam spread adjusting optical system 454. Thereafter, the measurement laser light may be condensed by the condenser optical system 45, and may be applied to the thin film on the workpiece 100.

The photosensor 452 may be placed at a position at which the measurement laser light reflected by the workpiece 100, passing through the beam splitter 420 through the condenser optical system 45, and reflected by the beam splitter 453 may enter the photosensor 452.

On the beam splitter 453, a film may be formed that may reflect the measurement laser light with reflectance of 50% and may transmit the measurement laser light with transmittance of 50%.

### [4.1.2 Operation]

The measurement laser light outputted from the measurement laser light source 451 may involve a predetermined spread angle by the beam spread adjusting optical system 454.

The measurement laser light with the predetermined spread angle may pass through the beam splitters 453 and 420 to enter the condenser optical system 45.

The measurement laser light entering the condenser optical system 45 may be condensed and applied to the region irradiated with the pulsed laser light in the thin film on the workpiece 100.

The measurement laser light applied to and reflected by the thin film on the workpiece 100 may pass through the beam splitter 420 through the condenser optical system 45, to enter the beam splitter 453. In the beam splitter 453, the entering light may be partly transmitted, and may be partly reflected. The light reflected by the beam splitter 453 may enter the photosensor 452. In the photosensor 452, light intensity of the entering light may be detected. A signal of the light intensity thus detected may be sent to the controlling section 80. In the controlling section 80, the reflectance of the thin film on the workpiece 100 may be calculated based on the signal of the light intensity thus sent.

### [4.1.3 Workings]

The measurement laser light outputted from the measurement laser light source 451 may be adjusted by the beam spread adjusting optical system 454 for application to the region subjected to the laser annealing in the thin film on the workpiece 100. In other words, it is possible to allow the region subjected to the laser annealing to coincide with the region subjected to the measurement of the reflectance, in the thin film on the workpiece 100.

It is possible to allow the measurement laser light outputted from the measurement laser light source 451 to enter the surface of the thin film on the workpiece 100 approximately perpendicularly. This allows for the measurement of the reflectance without being affected by polarized light.

### [4.2 Measurement of Transmittance]

### [4.2.1 Configuration]

The melt measuring section according to one example embodiment of the disclosure may use a melt measuring section configured to measure transmittance and involving a configuration illustrated in FIG. 16.

Specifically, the beam splitter 420 may be provided, instead of the third high reflective mirror 43 in the laser annealing apparatus illustrated in FIG. 1, etc.

On the beam splitter 420, the film may be formed that is configured to reflect the excimer laser light with high reflectance and to transmit the measurement laser light with the wavelength of 660 nm with high transmittance.

The fly eye lens 44 may be disposed on the optical path between the second high reflective mirror 42 and the beam splitter 420. The fly eye lens 44 may be formed to involve a smaller beam spread angle, i.e., to involve a spread angle that may allow the entire light to enter the condenser optical system 45, as compared to the fly eye lens 44 illustrated in FIG. 1.

The melt measuring section may include a measurement laser light source 461, a photosensor 462, and a beam spread adjusting optical system 463. In one embodiment of the disclosure, the phorosensor 462 may serve as a “light receiving section”. The beam spread adjusting optical system 463 may be disposed on the optical path of the measurement laser light outputted from the measurement laser light source 461. The measurement laser light source 461 may be placed at a position at which the measurement laser light outputted from the measurement laser light source 461 may be applied to the thin film on the workpiece 100 through the beam spread adjusting optical system 463, the beam splitter 420, and the condenser optical system 45. The photosensor 462 may be placed at a position at which the measurement laser light passing through the workpiece 100 may enter the photosensor 462.

The measurement laser light source 461 may be disposed to allow the optical path of the measurement laser light passing through the beam splitter 420 to be approximately the same as the optical path of the pulsed laser light for annealing.

The beam spread adjusting optical system 463 may be adjusted to allow the measurement laser light to be applied to an approximately same region as the region of the workpiece 100 irradiated with the pulsed laser light.

The measurement laser light outputted from the measurement laser light source 461 may pass through the beam splitter 420 through the beam spread adjusting optical system 463. Thereafter, the measurement laser light may be condensed by the condenser optical system 45, and may be applied to the thin film on the workpiece 100.

### [4.2.2 Operation]

The measurement laser light outputted from the measurement laser light source 461 may involve the predetermined spread angle by the beam spread adjusting optical system 463. The measurement laser light with the predetermined expansion angle may pass through the beam splitter 420 to enter the condenser optical system 45. The measurement laser light entering the condenser optical system 45 may be condensed and applied to the region irradiated with the pulsed laser light in the thin film on the workpiece 100.

The measurement laser light applied to and passing through the thin film on the workpiece 100 may enter the photosensor 462. In the photosensor 462, light intensity of the entering light may be detected. A signal of the light intensity thus detected may be sent to the controlling section 80. In the controlling section 80, transmittance of the thin film on the workpiece 100 may be calculated based on the signal of the light intensity thus sent.

### [4.2.3 Workings]

The measurement laser light outputted from the measurement laser light source 461 may be adjusted by the beam spread adjusting optical system 463 for application to the region subjected to the laser annealing in the thin film on the workpiece 100. In other words, it is possible to allow the region subjected to the laser annealing to coincide with the region subjected to the measurement of the transmittance, in the thin film on the workpiece 100.

### [4.2.4 Change in Transmittance in Melt Measuring Section]

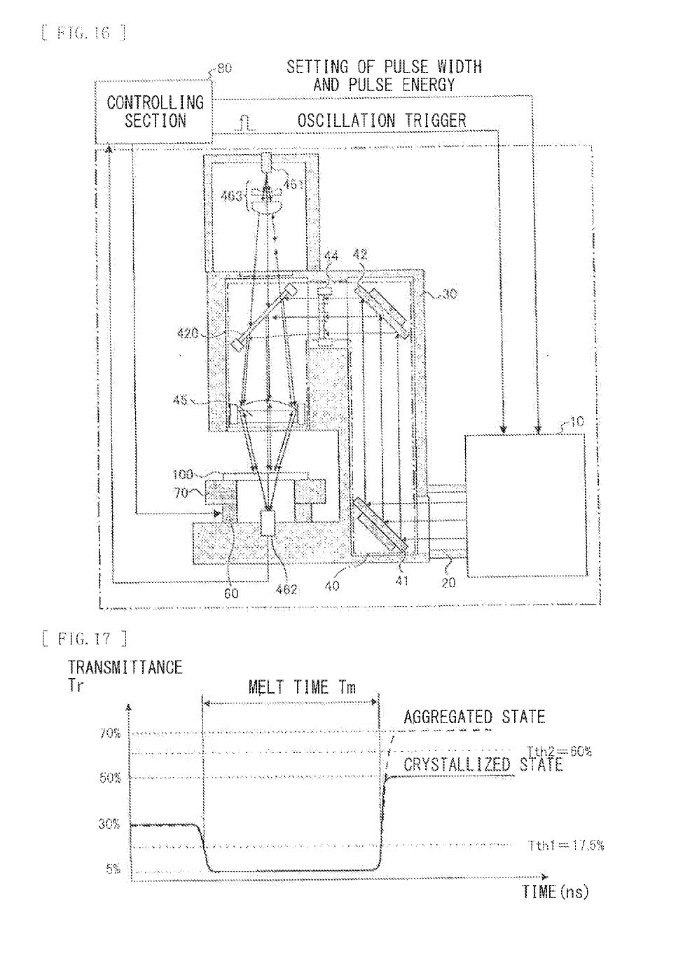

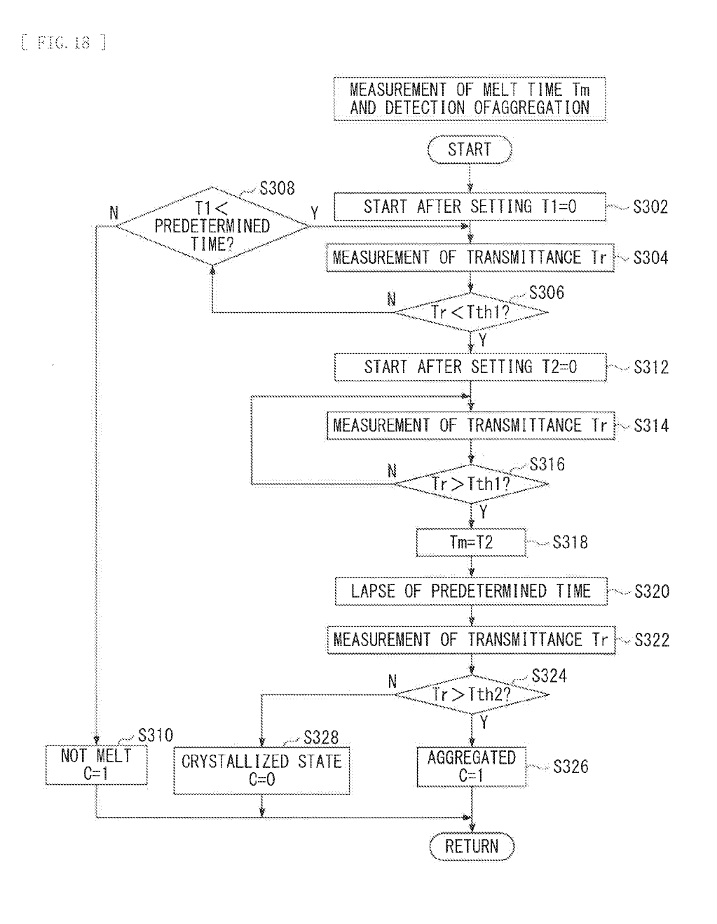

As described above, the laser light outputted from the measurement laser light source 461 may pass through the thin film formed on the workpiece 100, e.g., the amorphous silicon film, to enter the photosensor 462. The wavelength of the laser light outputted from the measurement laser light source 461 may be 660 nm. As illustrated in FIG. 17, the transmittance of the amorphous silicon film irradiated with the light with the wavelength of 660 nm may be approximately 30%. When the amorphous silicon film is irradiated with the pulsed laser light to melt, the transmittance may decrease to approximately 5%. When the irradiation with the pulsed laser light ends, the amorphous silicon film may be cooled and solidified. In such a solidified state, the amorphous silicon film may become a polysilicon film. The transmittance of the polysilicon film irradiated with the light with the wavelength of 660 nm may be approximately 50%.

It is to be noted that when the amorphous silicon film is irradiated with the pulsed laser light with too high fluence F (mJ/cm²), the silicon constituting the amorphous silicon film may be aggregated, which may cause scattering of the measurement laser light. This may result in a further increase in the transmittance up to, for example, approximately 70%.

Accordingly, as illustrated in FIG. 17, the melt time Tm may be obtained by measuring time during which the measured transmittance is kept lower than a transmittance reference value Tth1 wherein the transmittance reference value Tth1=17.5%, for example. Determination whether the film after the irradiation with the pulsed laser light is in the crystallized state or aggregated may be made by whether or not the transmittance after the irradiation with the pulsed laser light is higher than a transmittance reference value Tth2=60%. Specifically, determination of the crystallized state may be made when the transmittance after the irradiation with the pulsed laser light is lower than the transmittance reference value Tth2, while determination of aggregation may be made when the transmittance after the irradiation with the pulsed laser light is higher than the transmittance reference value Tth2.

### [4.2.5 Measurement of Melt Time Tm and Detection of Aggregation Using Change in Transmittance]

Description is made next on the measurement of the melt time Tm and the detection of aggregation by means of a change in the transmittance with reference to FIG. 18. FIG. 18 illustrates a subroutine of the measurement of the melt time Tm and the detection of aggregation by means of the change in the transmittance. The subroutine may correspond to an example of the subroutine of the measurement of the melt time Tm and the detection of aggregation in the step 108 in FIG. 8. The subroutine illustrated in FIG. 18 may be carried out in the step 108 in FIG. 8.

First, in step 302 (S302), time T1 of the first timer in the controlling section 80, etc. may be set to 0. Thereafter, the first timer may be started.

Next, in step 304 (S304), transmittance Tr of the thin film formed on the workpiece 100 may be measured. Specifically, the transmittance Tr may be measured as follows; the thin film formed on the workpiece 100 may be irradiated with the laser light outputted from the measurement laser light source 461 in the melt measuring section 50, and an amount of light passing through the workpiece 100 may be measured by the photosensor 462.

Next, in step 306 (S306), determination may be made whether or not the transmittance Tr measured in the step 304 is lower than the transmittance reference value Tth1. When the transmittance Tr measured in the step 304 is determined as being lower than the transmittance reference value Tth1, the flow may proceed to step 312. When the transmittance Tr measured in the step 304 is determined as not being lower than the transmittance reference value Tth1, the flow may proceed to step 308.

In the step 308 (S308), determination may be made whether or not the time T1 is shorter than the predetermined time. The predetermined time may be, for example, a same value as the pulse width of the pulsed laser light outputted from the excimer laser light source 110. When the time T1 is determined as not being shorter than the predetermined time, the flow may proceed to step 310. When the time T1 is determined as being shorter than the predetermined time, the flow may proceed to the step 304.

In the step 310 (S310), the thin film formed on the workpiece 100 may be determined as not having melted, and “−1” may be raised to the flag C in the controlling section 80, etc.

In the step 312 (S312), time T2 of the second timer in the controlling section 80, etc. may be set to 0. Thereafter, the second timer may be started.

Next, in step 314 (S314), the transmittance Tr of the thin film formed on the workpiece 100 may be measured. Specifically, the transmittance Tr may be measured in a similar manner to the step 304.

Next, in step 316 (S316), determination may be made whether or not the transmittance Tr measured in the step 314 is higher than the transmittance reference value Tth1. When the transmittance Tr measured in the step 314 is determined as being higher than the transmittance reference value Tth1, the flow may proceed to step 318. When the transmittance Tr measured in the step 314 is determined as not being higher than the transmittance reference value Tth1, the flow may proceed to the step 314.

In the step 318 (S318), a value of the time T2 may be set to Tm.

Next, in step 320 (S320), a lapse of predetermined time may be expected. The predetermined time may be time necessary to determine exactly whether or not the thin film formed on the workpiece 100 is in the crystallized state or aggregated.

Next, in step 322 (S322), the transmittance Tr of the thin film formed on the workpiece 100 may be measured. Specifically, the transmittance Tr may be measured in the similar manner to the step 304.

Next, in step 324 (S324), determination may be made whether or not the transmittance Tr measured in the step 322 is higher than the transmittance reference value Tth2. When the transmittance Tr measured in the step 322 is determined as being higher than the transmittance reference value Tth2, the flow may proceed to step 326. When the transmittance Tr measured in the step 322 is determined as not being higher than the transmittance reference value Tth2, the flow may proceed to step 328.

In the step 326 (S326), the thin film formed on the workpiece 100 may be determined as being aggregated, and “1” may be raised to the flag C in the controlling section 80, etc.

In the step 328 (S328), the thin film formed on the workpiece 100 may be determined as being in the crystallized state, and “0” may be raised to the flag C in the controlling section 80, etc.

Here, when processing should fail in catching up with execution of the above-described flowchart, measurement data of the photosensor 462 may be temporarily written in the undepicted storage section in the controlling section 80, etc. After completion of the measurement of the photosensor 462, data stored in the undepicted storage section in the controlling section 80, etc. may be read out to exert the above-described flowchart.

### [5. Other Liquid Supplying Sections]

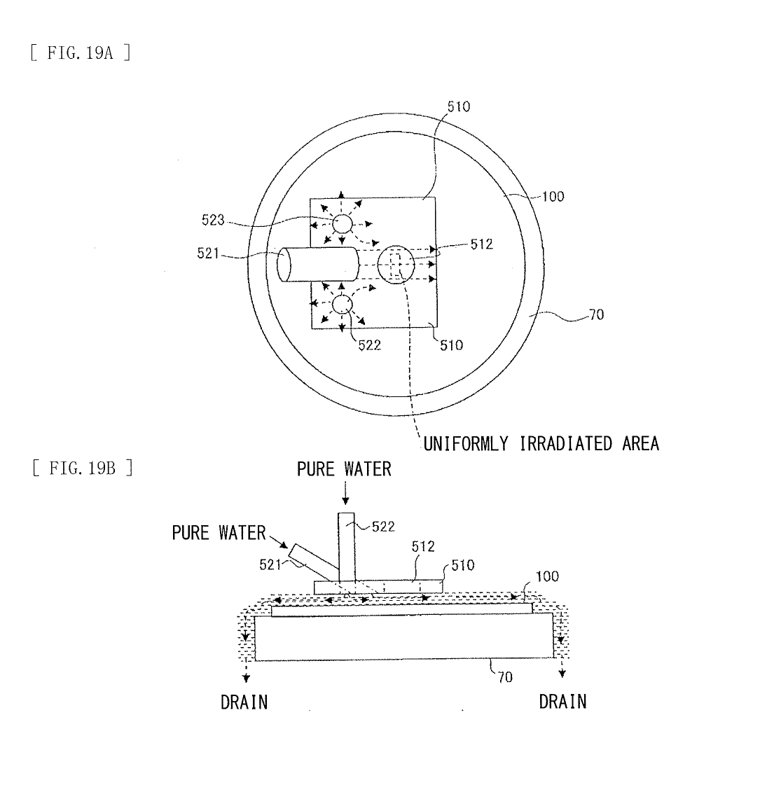

The plate and the tube in the liquid supplying section may involve other configurations than the configuration illustrated in FIG. 10. For example, as illustrate in FIGS. 19A and 19B, a configuration in which a first tube 521, a second tube 522, and a third tube 523 are coupled to a plate 510 may be also possible. It is to be noted that FIG. 19A is a top view of a portion including the plate 510 while FIG. 19B is a side view of the portion including the plate 510.

The first tube 521 may be placed on the plate 510 at a predetermined angle. The second tube 522 and the third tube 523 may be perpendicular to the plate 510 and may be placed on both sides of the first tube 521. The first tube 521, the second tube 522, and the third tube 523 may be coupled to a pump that is not illustrated in FIGS. 19A and 19B.

The pure water may be allowed to flow through the first tube 521, the second tube 522, and the third tube 523 at predetermined flow rates. This may make it possible to improve uniformity in a speed of the pure water flowing in the region irradiated with the pulsed laser light.

### [6. Et Cetera]

### [6.1 Power Circuit of Excimer Laser Light Source]

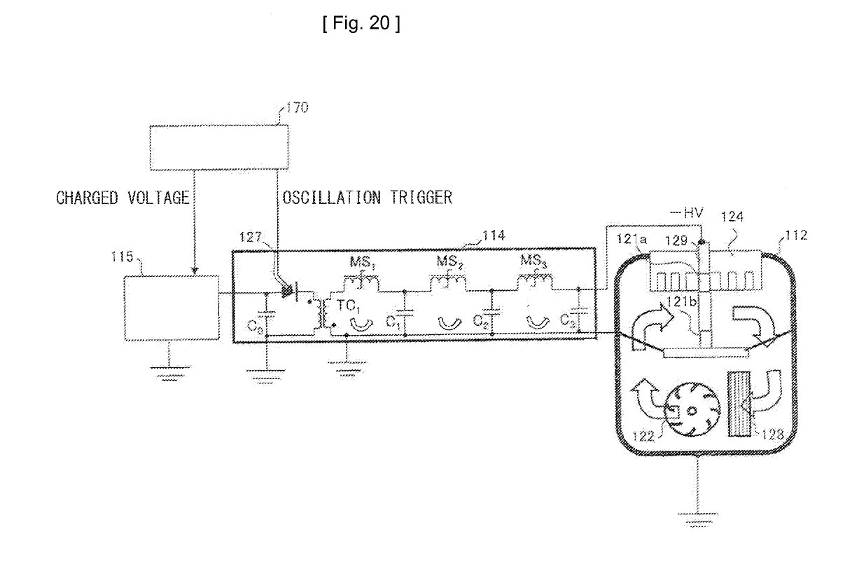

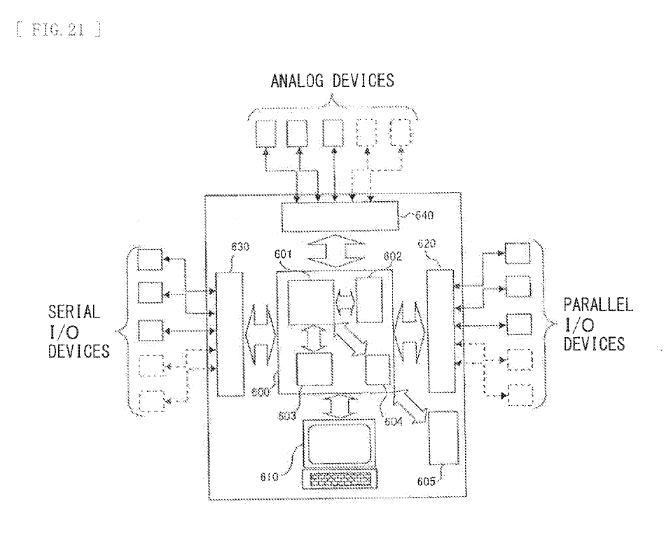

Description is given next on the PPM 114 and the charger 115 in the excimer laser light source 110 with reference to FIG. 20. FIG. 20 illustrates an electric circuit of the PPM 114, the charger 115, etc. It is to be noted that a heat exchanger 128 may be provided in the laser chamber 112 of the excimer laser light source 110, and that the pair of electrodes 121 may include the electrode 121a and the electrode 121b. A current introduction terminal 129 may be provided that connects the electrode 121a as one of the pair of the electrodes 121 and the PPM 114. The other electrode 121b may be grounded.

The PPM 114 may include a semiconductor switch that serves as the switch 127, magnetic switches MS₁, MS₂, and MS₃, a capacitor C₀, capacitors C₁, C₂, and C₃, and a transformer TC₁. When a time integration value of a voltage applied to a magnetic switch reaches a threshold value, a current becomes likely to flow through the relevant magnetic switch. In the following description, a state in which a current becomes likely to flow through the magnetic switch is referred to as “the magnetic switch is closed”. The threshold value may differ for each magnetic switch.

The switch 127 may be provided between the capacitor C₀ and the transformer TC₁. The magnetic switch MS₁ may be provided between the transformer TC₁ and the capacitor C₁. The magnetic switch MS₂ may be provided between the capacitor C₁ and the capacitor C₂. The magnetic switch MS₃ may be provided between the capacitor C₂ and the capacitor C₃.

The laser controller 170 may set, in the charger 115, a command value of a voltage Vhv when an electric charge is charged in the capacitor C₀. Based on the command value, the charger 115 may charge the capacitor C₀ with the electric charge so as to allow a voltage applied to the capacitor C₀ to become Vhv.

Next, when a signal is sent to the switch 127 from the laser controller 170, the switch 127 may be closed, allowing a current to flow from the capacitor C₀ to the transformer TC₁.

Next, the magnetic switch MS₁ may be closed, allowing the current to flow from the transformer TC₁ to the capacitor C₁ to cause the electric charge to be charged in the capacitor C₁. At this occasion, a pulse width of the current may become shorter, allowing the electric charge to be charged in the capacitor C₁.

Next, the magnetic switch MS₂ may be closed, allowing the current to flow from the capacitor C₁ to the capacitor C₂ to cause the electric charge to be charged in the capacitor C₂. At this occasion, the pulse width of the current may become shorter, allowing the electric charge to be charged in the capacitor C₂.

Next, the magnetic switch MS₃ may be closed, allowing the current to flow from the capacitor C₂ to the capacitor C₃ to cause the electric charge to be charged in the capacitor C₃. At this occasion, the pulse width of the current may become shorter, allowing the electric charge to be charged in the capacitor C₃.

Thus, the current may flow sequentially, from the transformer TC₁ to the capacitor C₁, from the capacitor C₁ to the capacitor C₂, from the capacitor C₂ to the capacitor C₃, allowing the pulse width to be shortened to cause the electric charge to be charged in the capacitor C₃.

Thereafter, a voltage may be applied, from the capacitor C₃, between the electrode 121a and the electrode 121b provided in the laser chamber 112, allowing discharge to be generated in the laser gas between the electrode 121a and the electrode 121b.

### [6.2 Controlling Section]

Description is given next on controllers including the controlling section 80, the laser controller, etc. with reference to FIG. 21.

The controllers including the controlling section 80, etc. each may be configured of a general purpose control device such as, but not limited to, a computer, a programmable controller, etc. An exemplary configuration may be as follows.

The controller may include a processing unit 600, a storage memory 605, a user interface 610, a parallel input/output (I/O) controller 620, a serial I/O controller 630, and an analog-to-digital (A/D) and digital-to-analog (D/A) converter 640. The storage memory 605 may be coupled to the processing unit 600.

The processing unit 600 may include a central processing unit (CPU) 601, a memory 602, a timer 603, and a graphics processing unit (GPU) 604. The memory 602 may be coupled to the CPU 601.

The processing unit 600 may load programs stored in the storage memory 605 to execute the loaded programs. The processing unit 600 may read data from the storage memory 605 and may write data in the storage memory 605, in accordance with execution of the programs.

The parallel I/O controller 620 may be coupled to a device operable to perform communication through a parallel I/O port. The parallel I/O controller 620 may control communication with use of digital signals through the parallel I/O port, performed when the processing unit 600 executes a program.

The serial I/O controller 630 may be coupled to a device operable to perform communication through a serial I/O port. The serial I/O controller 630 may control communication with use of digital signals through the serial I/O port, performed when the processing unit 600 executes a program.

The A/D and D/A converter 640 may be coupled to a device operable to perform communication through an analog port. The A/D and D/A converter 640 may control communication with use of analog signals through the analog port, performed when the processing unit 600 executes a program.

The user interface 610 may provide an operator with display showing a progress of the execution of the programs performed by the processing unit 600, such that the operator is able to instruct the processing unit 600 to stop the execution of the programs or to execute an interruption routine.

The CPU 601 of the processing unit 600 may execute a calculation processing of the programs. The memory 602 may be a work area in which programs to be executed by the CPU 601 and data to be used for a calculation process of the CPU 601 are held temporarily. The timer 603 may measure time or elapsed time to provide the CPU 601 with the time or the elapsed time in accordance with the execution of the programs. The GPU 604 may process image data inputted to the processing unit 600 in accordance with the execution of the programs, and may provide the CPU 601 with a result of the processing of the image data.

Non-limiting examples of the device coupled to the parallel I/O controller 620 and operable to perform communication through the parallel I/O port may include the charger 115, the drivers 134 and 145, other controllers, etc.

Non-limiting examples of the device coupled to the serial I/O controller 630 and operable to perform communication through the serial I/O port may include other controllers, etc.

Non-limiting examples of the device coupled to the A/D and D/A converter 640 and operable to perform communication through the analog port may include various sensors such as, but not limited to, the pulse energy sensor 152, the photosensor 52, etc.

The foregoing description is intended to be merely illustrative rather than limiting. It should therefore be appreciated that variations may be made in example embodiments of the disclosure by persons skilled in the art without departing from the scope as defined by the appended claims.

The terms used throughout the specification and the appended claims are to be construed as “open-ended” terms. For example, the term “include” and its grammatical variants are intended to be non-limiting, such that recitation of items in a list is not to the exclusion of other like items that can be substituted or added to the listed items. The term “have” and its grammatical variants are intended to be non-limiting, such that recitation of items in a list is not to the exclusion of other like items that can be substituted or added to the listed items. Also, the singular forms “a”, “an”, and “the” used in the specification and the appended claims include plural references unless expressly and unequivocally limited to one referent.

What is claimed is:

1. A laser annealing apparatus, comprising:
a laser light source section configured to output pulsed laser light to be applied to a thin film formed on a workpiece;
a pulse width varying section configured to vary a pulse width of the pulsed laser light;
a melt state measuring section configured to detect that the thin film irradiated with the pulsed laser light is in a melt state; and
a controlling section configured to determine, based on a result of detection by the melt state measuring section, a duration of time during which the thin film is in the melt state, and to control the pulse width varying section to allow the duration of time to be of a predetermined length.

2. The laser annealing apparatus according to claim 1, wherein the melt state measuring section measures one of reflectance of the thin film formed on the workpiece and transmittance of the workpiece to detect that the thin film is in the melt state.

3. The laser annealing apparatus according to claim 1, wherein the pulse width varying section is an optical pulse stretcher.

4. The laser annealing apparatus according to claim 1, further comprising a liquid supplying section configured to supply a liquid to a surface of the workpiece.

5. The laser annealing apparatus according to claim 1, wherein the melt state measuring section includes:
a measurement laser light source configured to output measurement laser light; and
a light receiving section configured to detect reflected light from the thin film, the reflected light being derived from the measurement laser light source to be applied to the thin film.

6. The laser annealing apparatus according to claim 1, wherein the melt state measuring section includes:
a measurement laser light source configured to output measurement laser light; and
a light receiving section configured to detect transmitted light having been transmitted through the workpiece, the transmitted light being derived from the measurement laser light source to be applied to the thin film.

7. A laser annealing apparatus, comprising:
a laser light source section including pairs of electrodes, and configured to output pulsed laser light to be applied to a thin film formed on a workpiece;
a delay circuit configured to provide a time delay from discharge of a first pair of the pairs of electrodes to discharge of a second pair of the pairs of electrodes;
a melt state measuring section configured to detect that the thin film irradiated with the pulsed laser light is in a melt state; and
a controlling section configured to determine, based on a result of detection by the melt state measuring section, a duration of time during which the thin film is in the melt state, and to control the delay circuit to allow the duration of time to be of a predetermined length.

8. The laser annealing apparatus according to claim 7, wherein the melt state measuring section measures one of reflectance of the thin film formed on the workpiece and transmittance of the workpiece to detect that the thin film is in the melt state.

9. The laser annealing apparatus according to claim 7, further comprising a liquid supplying section configured to supply a liquid to a surface of the workpiece.

10. The laser annealing apparatus according to claim 7, wherein the melt state measuring section includes:
a measurement laser light source configured to output measurement laser light; and
a light receiving section configured to detect reflected light from the thin film, the reflected light being derived from the measurement laser light source to be applied to the thin film.

11. The laser annealing apparatus according to claim 7, wherein the melt state measuring section includes:
a measurement laser light source configured to output measurement laser light; and
a light receiving section configured to detect transmitted light having been transmitted through the workpiece, the transmitted light being derived from the measurement laser light source to be applied to the thin film.
